(19) United States
(12) Patent Application Publication
(10) Pub. No.: US 2026/0068508 A1
(43) Pub. Date: Mar. 5, 2026

(54) DISPLAY DEVICE AND ELECTRONIC APPARATUS INCLUDING THE SAME

(71) Applicant: SAMSUNG DISPLAY CO., LTD., YONGIN-SI (KR)

(72) Inventor: JONGHWAN CHO, Yongin-si (KR)

(21) Appl. No.: 19/258,133

(22) Filed: Jul. 2, 2025

(30) Foreign Application Priority Data
Aug. 30, 2024 (KR) 10-2024-0117333

(51) Int. Cl. H10K 59/80; C09D 1/00; C09D 5/00; C09D 7/20; C09D 7/40; C09D 7/62; C09D 159/00; C09D 183/04

(52) U.S. Cl. CPC H10K 59/8791; C09D 1/00; C09D 5/006; C09D 7/20; C09D 7/62; C09D 7/67; C09D 159/00; C09D 183/04; H10K 59/873

(57) ABSTRACT

A display device includes: a display panel configured to fold along a folding axis; and a protective member disposed on the display panel, wherein the protective member includes: a protective base layer; a hard coating layer including a polymer derived from a coating composition, wherein the hard coating layer is disposed on the protective base layer; and an antireflection layer including a high refractive index layer and a low refractive index layer disposed on the high refractive index layer, wherein the antireflection layer is disposed on the hard coating layer, wherein the coating composition includes a silsesquioxane-based resin, an oxetane-based resin, a photopolymerization initiator, and silica nanoparticles, and wherein a first weight of the silica nanoparticles is about 3 wt % to about 5 wt % based on a total weight of the coating composition.

### CROSS-REFERENCE TO RELATED APPLICATION

This U.S. non-provisional patent application claims priority under 35 U.S.C. § 119 to Korean Patent Application No. 10-2024-0117333, filed on Aug. 30, 2024, the disclosure of which is incorporated by reference herein in its entirety.

### TECHNICAL FIELD

The present invention relates to a foldable display device and an electronic apparatus including the display device.

### DISCUSSION OF THE RELATED ART

Various electronic apparatuses such as televisions, mobile phones, tablet computers, and game consoles are currently under development. Recently, flexible electronic apparatuses including flexible display panels that are capable of folding, rolling or sliding have been under development. Unlike rigid electronic apparatuses, flexible electronic apparatuses may be folded or rolled. Flexible electronic apparatuses, whose shapes may be changed in various ways, may be carried regardless of the existing screen size, thereby increasing user convenience. Flexible electronic apparatuses may include layers to maintain flexible operation reliability.

### SUMMARY

According to an embodiment of the present invention, a display device includes: a display panel configured to fold along a folding axis; and a protective member disposed on the display panel, wherein the protective member includes: a protective base layer; a hard coating layer including a polymer derived from a coating composition, wherein the hard coating layer is disposed on the protective base layer; and an antireflection layer including a high refractive index layer and a low refractive index layer disposed on the high refractive index layer, wherein the antireflection layer is disposed on the hard coating layer, wherein the coating composition includes a silsesquioxane-based resin, an oxetane-based resin, a photopolymerization initiator, and silica nanoparticles, and wherein a first weight of the silica nanoparticles is about 3 wt % to about 5 wt % based on a total weight of the coating composition.

In an embodiment of the present invention, a sum of a second weight of the silsesquioxane-based resin and a third weight of the oxetane-based resin is about 93 wt % to about 95 wt % based on the total weight of the coating composition.

In an embodiment of the present invention, the silsesquioxane-based resin includes at least one of a T-type silsesquioxane unit, a D-type silsesquioxane unit, or an M-type silsesquioxane unit.

In an embodiment of the present invention, the silsesquioxane-based resin includes 7 or 8 siloxane units.

In an embodiment of the present invention, the oxetane-based resin includes a moiety represented by a following Formula 1.

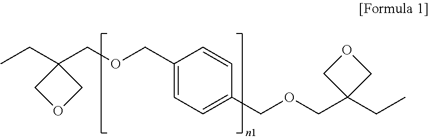

In Formula 1, n1 is an integer of 3 to 100.

In an embodiment of the present invention, the photopolymerization initiator includes a triarylsulfonium hexafluoroantimonate salt.

In an embodiment of the present invention, a weight of the photopolymerization initiator is about 2 wt % or less based on the total weight of the coating composition.

In an embodiment of the present invention, a diameter of the silica nanoparticles is about 20 nm to about 60 nm.

In an embodiment of the present invention, the silica nanoparticle includes a hydroxyl group on a surface thereof.

In an embodiment of the present invention, the coating composition further includes a solvent, and the solvent includes at least one of 1-methyoxy-2-methyl-2-propanol, 1-methoxy-2-propanol, or 2-butanone.

In an embodiment of the present invention, the high refractive index layer includes niobium pentoxide (Nb₂O₅) and titanium dioxide (TiO₂), and based on a sum of a fourth weight of the niobium pentoxide and a fifth weight of the titanium dioxide, a ratio of the fourth weight and the fifth weight is about 7:3 to about 9:1.

In an embodiment of the present invention, each of the high refractive index layer and the low refractive index layer is provided in multiples, and the multiple high refractive index layers and the multiple low refractive index layers are alternately disposed on the hard coating layer.

In an embodiment of the present invention, a thickness of the hard coating layer is about 1 μm to about 8 μm.

In an embodiment of the present invention, the hard coating layer has a specular component included (SCI) reflectivity of about 0.5% to about 1.5%.

In an embodiment of the present invention, a hardness of the hard coating layer is about 0.22 GPa to about 0.32 GPa, and an elastic modulus of the hard coating layer is about 2.78 GPa to about 3.78 GPa.

In an embodiment of the present invention, the protective base layer includes at least one among polyethylene terephthalate, polyimide, polyacrylate, polymethyl methacrylate, polycarbonate, polyethylene naphthalate, polyvinylidene chloride, polyvinylidene difluoride, polystyrene, or an ethylene vinyl alcohol copolymer.

According to an embodiment of the present invention, an electronic apparatus includes: a display device including a module area; and an electronic module disposed to correspond to the module area, wherein the display device includes: a display panel configured to fold along a folding axis; and a protective member disposed on the display panel, wherein the protective member includes: a protective base layer; a hard coating layer including a polymer derived from a coating composition, wherein the hard coating layer is disposed on the protective base layer; and an antireflection layer including a high refractive index layer and a low refractive index layer disposed on the high refractive index layer, wherein the antireflection layer is disposed on the hard coating layer, wherein the coating composition includes a silsesquioxane-based resin, an oxetane-based resin, a photopolymerization initiator, and silica nanoparticles, and wherein a first weight of the silica nanoparticles is about 3 wt % to about 5 wt % based on a total weight of the coating composition.

In an embodiment of the present invention, a sum of a second weight of the silsesquioxane-based resin and a third weight of the oxetane-based resin is about 93 wt % to about 95 wt % based on the total weight of the coating composition.

In an embodiment of the present invention, the photopolymerization initiator includes a triarylsulfonium hexafluoroantimonate salt, and the oxetane-based resin includes a moiety represented by a following Formula 1.

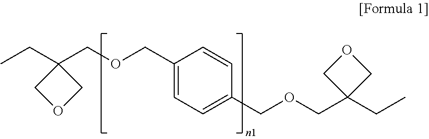

In Formula 1, n1 is an integer of 3 to 100.

According to an embodiment of the present invention, an electronic apparatus includes: a processor; a memory having stored application programs for execution by the processor; a display device includes: a display panel configured to fold along a folding axis; and a protective member disposed on the display panel, wherein the protective member includes: a protective base layer; a hard coating layer including a polymer derived from a coating composition, wherein the hard coating layer is disposed on the protective base layer; and an antireflection layer including a high refractive index layer and a low refractive index layer disposed on the high refractive index layer, wherein the antireflection layer is disposed on the hard coating layer, wherein the high refractive index layer includes niobium pentoxide and titanium dioxide, wherein the coating composition includes a silsesquioxane-based resin, an oxetane-based resin, a photopolymerization initiator, and silica nanoparticles, and wherein a first weight of the silica nanoparticles is about 3 wt % to about 5 wt % based on a total weight of the coating composition; and a user interface configured to sense user input via touch or cursor select of an icon presented on the display panel, wherein the processor is caused to execute one or more of the stored application programs upon receipt of the user input.

### BRIEF DESCRIPTION OF THE FIGURES

The above and other objects and features of the present invention will become apparent by describing in detail embodiments thereof with reference to the accompanying drawings.

FIG. 1 is a perspective view illustrating an electronic apparatus of an embodiment of the present invention;

FIG. 2 is a perspective view illustrating an electronic apparatus of an embodiment of the present invention;

FIG. 3 is a plan view illustrating an electronic apparatus of an embodiment of the present invention;

FIG. 4 is a perspective view illustrating an electronic apparatus of an embodiment of the present invention;

FIG. 5 is a perspective view illustrating an electronic apparatus of an embodiment of the present invention;

FIG. 6 is a perspective view illustrating an electronic apparatus of an embodiment of the present invention;

FIG. 7 is a perspective view illustrating an electronic apparatus of an embodiment of the present invention;

FIG. 8 is an exploded perspective view illustrating an electronic apparatus of an embodiment of the present invention;

FIG. 9 is a cross-sectional view illustrating a portion corresponding to line I-I′ in FIG. 8;

FIG. 10 is an enlarged cross-sectional view illustrating an area XX′ in FIG. 9;

FIG. 11 is a diagram illustrating a silica nanoparticle according to an embodiment of the present invention;

FIG. 12 is a cross-sectional view illustrating a portion corresponding to line II-II′ in FIG. 8;

FIG. 13 is a block diagram illustrating an electronic device according to an embodiment of the present invention; and

FIG. 14 is a view illustrating electronic apparatuses according to various embodiments.

### DETAILED DESCRIPTION OF THE EMBODIMENTS

The present invention may have various modifications and may be embodied in different forms, and example embodiments will be explained in detail with reference to the accompany drawings. The present invention may, however, be embodied in different forms and should not be construed as limited to the embodiments set forth herein. Rather, all modifications, equivalents, and substituents which are included in the spirit and technical scope of the present invention should be included in the present invention.

In the description, when an element (or a region, a layer, a part, or the like) is referred to as being “on,” “connected with” or “combined with” another element, it can be directly disposed on/connected with/bonded to the other element, or intervening third elements may also be disposed therebetween.

Like reference numerals refer to like elements throughout the specification and drawings. In addition, various thicknesses, lengths, and angles are shown and while the arrangement shown does indeed represent an embodiment of the present invention, it is to be understood that modifications of the various thicknesses, lengths, and angles may be possible within the spirit and scope of the present disclosure and the present disclosure is not necessarily limited to the particular thicknesses, lengths, and angles shown The term “and/or” may include one or more combinations that may define relevant elements.

It will be understood that, although the terms “first”, “second”, or the like may be used herein to describe various elements, these elements should not be limited by these terms. These terms are only used to distinguish one element from another element. For example, a first element could be termed a second element without departing from the scope of the present invention. Similarly, a second element could be termed a first element. As used herein, the singular forms are intended to include the plural forms as well, unless the context clearly indicates otherwise.

Also, terms such as “below,” “lower,” “above,” and “upper” may be used to describe the relationships of the components illustrated in the drawings. These terms are used as a spatially relative concept and are described based on the directions indicated in the drawings. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which the present invention belongs. In addition, it will be further understood that terms, such as those defined in commonly used dictionaries, should be interpreted as having a meaning that is consistent with their meaning in the context of the relevant art and will not be interpreted in an idealized or overly formal sense unless expressly defined so herein.

In the description, an alkyl group may be linear, branched, or cyclic. The number of carbon atoms of the alkyl group may be 1 to 60, 1 to 50, 1 to 30, 1 to 20, 1 to 10, or 1 to 6. Examples of the alkyl group may include methyl, ethyl, n-propyl, isopropyl, cyclopropyl, n-butyl, s-butyl, t-butyl, i-butyl, 2-ethylbutyl, 3,3-dimethylbutyl, cyclobutyl, n-pentyl, i-pentyl, neopentyl, t-pentyl, 1-methylpentyl, 3-methylpentyl, 2-ethylpentyl, 4-methyl-2-pentyl, cyclopentyl, n-hexyl, 1-methylhexyl, 2-ethylhexyl, 2-butylhexyl, cyclohexyl, 4-methylcyclohexyl, 4-butylcyclohexyl, n-heptyl, 1-methylheptyl, 2,2-dimethylheptyl, 2-ethylheptyl, 2-butylheptyl, cycloheptyl, bicycloheptyl, n-octyl, t-octyl, 2-ethyloctyl, 2-butyloctyl, 2-hexyloctyl, 3,7-dimethyloctyl, cyclooctyl, n-nonyl, cyclononyl, n-decyl, cyclodecyl, norbornyl, 1-adamantyl, 2-adamantyl, isobornyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldodecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-icosyl, 2-ethylicosyl, 2-butylicosyl, 2-hexylicosyl, 2-octylicosyl, n-henicosyl, n-docosyl, n-tricosyl, n-tetracosyl, n-pentacosyl, n-hexacosyl, n-heptacosyl, n-octacosyl, n-nonacosyl, and n-triacontyl, but present invention is not limited thereto.

In the description, an alkenyl group means a hydrocarbon group having at least one carbon double bond in the middle or terminal of an alkyl group having two or more carbon atoms. The alkenyl group may be linear or branched. The number of carbon atoms of the alkenyl group is not particularly limited, but may be 2 to 60, 2 to 30, 2 to 20, or 2 to 10. Examples of the alkenyl group may include, but are not limited to, a vinyl group, a 1-butenyl group, a 1-pentenyl group, a 1,3-butadienyl aryl group, a styrenyl group, a styrylvinyl group, or the like.

In the description, an aryl group means any functional group or substituent derived from an aromatic hydrocarbon ring. The aryl group may be a monocyclic aryl group or a polycyclic aryl group. The number of carbon atoms forming the ring of the aryl group may be 6 to 60, 6 to 30, 6 to 20, or 6 to 15. Examples of the aryl group may include, but are not limited to, a phenyl group, a naphthyl group, a fluorenyl group, an anthracenyl group, a phenanthryl group, a biphenyl group, a terphenyl group, a quarterphenyl group, a quinquephenyl group, a sexiphenyl group, a triphenylenyl group, a pyrenyl group, a benzofluoranthenyl group, a chrysenyl group, or the like.

In the description, an alkoxy group may mean an alkyl group defined above to which an oxygen atom is bonded. The alkoxy group may be linear, branched, or cyclic. The number of carbon atoms of the alkoxy group is not particularly limited, but may be, for example, 1 to 60, 1 to 30, 1 to 20, or 1 to 10. Examples of the alkoxy group include, but are not limited to, methoxy, ethoxy, n-propoxy, isopropoxy, butoxy, pentyloxy, hexyloxy, octyloxy, nonyloxy, decyloxy, or the like.

In the description, “ [symbol] ” indicates a bonding position.

Embodiments of the present invention relate to a foldable display device and an electronic apparatus that incorporates the foldable display device. The display device includes a flexible display panel capable of folding along a folding axis and is reinforced with a protective member. The protective member may include multiple layers: a protective base layer, a hard coating layer for durability, and an antireflection layer to improve visual clarity. The composition of the protective member may ensure high reliability, allowing the display device to endure repeated folding and unfolding without compromising functionality or appearance.

According to embodiments of the present invention, the hard coating layer may be derived from a coating composition including a silsesquioxane-based resin, oxetane-based resin, photopolymerization initiator, and silica nanoparticles. This composition provides a balance between hardness and flexibility, enabling the display device to handle low-curvature folding (e.g., with a radius of curvature as small as about 1.5 mm). The silica nanoparticles, carefully sized and proportioned, increase durability and wear resistance, ensuring the display device remains intact and scratch-resistant during usage.

Additionally, the antireflection layer includes alternating high and low refractive index materials, such as niobium pentoxide and titanium dioxide for the high index layer and silicon dioxide for the low index layer. These layers may minimize glare and increase display quality by reducing reflectivity. The display device according to embodiments of the present invention may ensure both flexibility and robustness, thereby maintaining performance during folding and unfolding cycles.

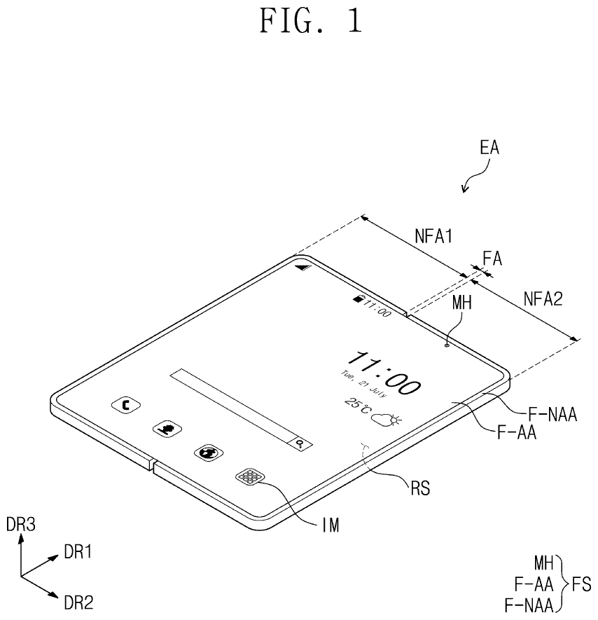

Hereinafter, a display device and an electronic apparatus including the display device according to an embodiment of the present invention will be described with reference to the drawings. FIG. 1 is a perspective view of an electronic apparatus EA in an unfolded state according to an embodiment of the present invention.

The electronic apparatus EA according to an embodiment of the present invention may be an apparatus that is activated according to an electrical signal. For example, the electronic apparatus EA may be a smartphone, a tablet, a car navigation system, a game console, or a wearable apparatus, but an embodiment of the present invention is not limited thereto. In FIG. 1 and the like, the electronic apparatus EA is illustrated as a smartphone, as an example.

The electronic apparatus EA may include a first display surface FS that is parallel to a plane that is defined by a first directional axis DR1 (or a first direction DR1) and a second directional axis DR2 (or a second direction DR2) intersecting the first directional axis DR1. The electronic apparatus EA may provide an image IM to a user through the first display surface FS. The electronic apparatus EA may display an image IM toward a third directional axis DR3 (or a third direction DR3) through the first display surface FS that is parallel to each of the first directional axis DR1 and the second directional axis DR2. The image IM may include a dynamic image and a static image.

In the description, the first directional axis DR1 and the second directional axis DR2 may be orthogonal to each other, and the third directional axis DR3 may be a normal direction to a plane defined by the first directional axis DR1 and the second directional axis DR2. The thickness direction of the electronic apparatus EA may be a direction that is parallel to the third directional axis DR3. The front surface (or, e.g., upper surface) and the back surface (or, e.g., lower surface) of the electronic apparatus EA are opposite to each other in the third directional axis DR3, and the normal direction of each of the front surface (or, e.g., upper surface) and the back surface (or, e.g., lower surface) may be parallel to the third directional axis DR3. The front surface (or, e.g., upper surface) of the electronic apparatus EA may correspond to the first display surface FS, and the back surface (or, e.g., lower surface) refers to a surface that is spaced from the first display surface FS along the third directional axis DR3. In addition, the back surface (or, e.g., lower surface) of the electronic apparatus EA may correspond to a second display surface RS described later. For example, the upper side refers to a direction approaching the first display surface FS, and the lower side refers to a direction extending away from the first display surface FS.

The cross-section refers to a surface parallel to a thickness direction DR3, and the plane refers to a surface perpendicular to the thickness direction DR3. The plane refers to a plane defined by the first directional axis DR1 and the second directional axis DR2.

The directions indicated by the first to third directional axes DR1, DR2 and DR3 described in the description are relative concepts and may be converted into other directions. In addition, the directions indicated by the first to third directional axes DR1, DR2 and DR3 may be described as the first to third directions, and the same drawing symbols may be used.

The electronic apparatus EA may detect external inputs that are applied from the outside. The external inputs may include various types of inputs provided from the outside of the electronic apparatus EA. For example, the external inputs may include contact by a part of the body such as a user's hand, as well as external inputs (for example, hovering) applied in proximity to the electronic apparatus EA or at a predetermined distance. As another example, external inputs may include a contact by an object such as a stylus. In addition, the external inputs may have various forms such as force, pressure, temperature and light.

The electronic apparatus EA may include the first display surface FS and the second display surface RS. The first display surface FS may include a first active area F-AA, a first peripheral area F-NAA, and a sub-area MH. The second display surface RS may be defined as a surface facing at least a portion of the first display surface FS. For example, the second display surface RS may be defined as a portion of the rear surface of the electronic apparatus EA.

The first active area F-AA may be an area activated according to an electrical signal. The first active area F-AA may be an area where an image IM is displayed and various types of external inputs may be detected.

The first peripheral area F-NAA may be adjacent to the first active area F-AA. The light transmittance of the first peripheral area F-NAA may be lower than the light transmittance of the first active area F-AA. The first peripheral area F-NAA may have a predetermined color. The first peripheral area F-NAA may at least partially surround the first active area F-AA. For example, the first peripheral area F-NAA may completely surround the first active area F-AA. Accordingly, the shape of the first active area F-AA may be substantially defined by the first peripheral area F-NAA. However, this is an illustration, and the first peripheral area F-NAA may be disposed adjacent to only one side of the first active area F-AA or may be omitted.

The sub-area MH may detect an external subject received through the display surfaces FS and RS or provide a sound signal such as a voice to the outside through the display surfaces FS and RS. An optical signal such as visible light or infrared light may move to the sub-area MH.

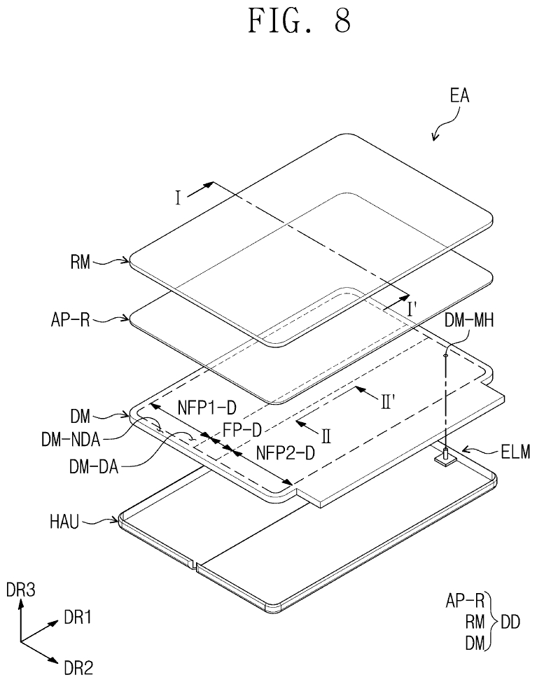

Various electronic modules ELM (FIG. 8) may be disposed to correspond to the sub-area MH. For example, the electronic module ELM (FIG. 8) may include at least one of a camera, a speaker, a light detection sensor, or a heat detection sensor. The electronic apparatus EA may include an electronic module ELM (FIG. 8) that captures an external image through by using visible light that passes through the sub-area MH and/or that determines the presence and/or accessibility of an external object by using infrared light. For instance, the electronic module ELM may utilize its visible light capabilities to capture a user's facial image for authentication purposes, ensuring secure access to the electronic apparatus EA. Simultaneously, the infrared light functionality may detect the proximity of a user's hand or face, enabling features such as gesture-based interactions or automatic screen activation when the electronic module ELM senses the user's presence. The electronic module ELM (FIG. 8) may include multiple configurations and is not limited to any one embodiment.

The sub-area MH may be disposed within the first active area F-AA. However, this is an illustration and is not limited to any one embodiment. For example, the sub-area MH may be surrounded by the first peripheral area F-NAA, or may be surrounded by the first active area F-AA and the first peripheral area F-NAA. Although one sub-area MH is illustrated in FIG. 1, multiple sub-areas MH may be provided.

The electronic apparatus EA of an embodiment of the present invention may include at least one folding area FA and multiple non-folding areas NFA1 and NFA2, extended from the folding area FA. For example, a first non-folding area NFA1, a folding area FA, and a second non-folding area NFA2 may be defined along the second direction DR2. For example, the folding area FA may be disposed between the first non-folding area NFA1 and the second non-folding area NFA2. The electronic apparatus EA, according to an embodiment of the present invention, may include a first non-folding area NFA1 and a second non-folding area NFA2 spaced apart from each other in the second direction DR2 with the folding area FA interposed therebetween. For example, the first non-folding area NFA1 may be disposed on one side of the folding area FA along the second direction DR2, and the second non-folding area NFA2 may be disposed on the other side of the folding area FA along the second direction DR2.

Although FIG. 1 and the like illustrate an electronic apparatus EA, according to an embodiment of the present invention, including one folding area FA, an embodiment of the present invention is not limited thereto, and multiple folding areas may be included in the electronic apparatus EA. For example, the electronic apparatus according to an embodiment of the present invention may include two or more folding areas, and may also include three or more non-folding areas disposed with each of the folding areas interposed therebetween.

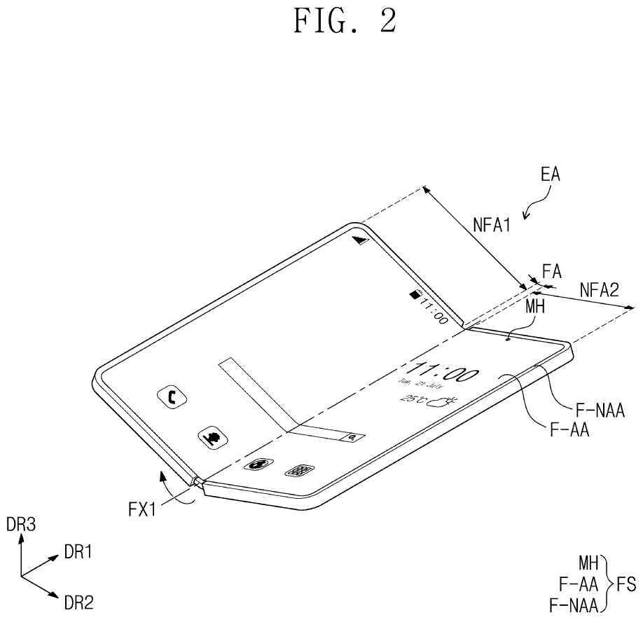

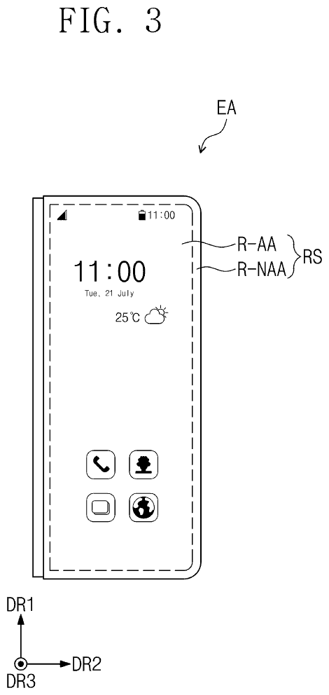

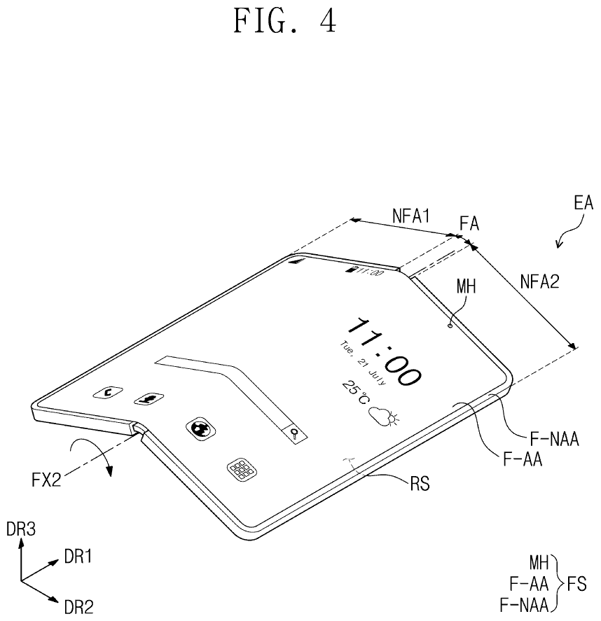

FIG. 2 is a perspective view illustrating a folding operation of an electronic apparatus EA according to an embodiment of the present invention. FIG. 3 is a plan view illustrating a folded state of an electronic apparatus EA according to an embodiment of the present invention. FIG. 4 is a perspective view illustrating a folding operation of an electronic apparatus EA according to an embodiment of the present invention.

Referring to FIG. 2, the electronic apparatus EA according to an embodiment of the present invention may be folded based on the first folding axis FX1 extended in the first direction DR1. In a folded state of the electronic apparatus EA, the folding area FA may have a predetermined curvature and a radius of curvature. The electronic apparatus EA may be folded based on the first folding axis FX1 so that the first non-folding area NFA1 and the second non-folding area NFA2 face each other and may be transformed into an in-folding state so that the first display surface FS is not exposed to the outside.

FIG. 3 may be a plan view illustrating the electronic apparatus EA in an in-folded state. Referring to FIG. 3, in the electronic apparatus EA according to an embodiment of the present invention, the second display surface RS may be visible to a user in an in-folded state. In this case, the second display surface RS may include a second active area R-AA, which displays an image, and a second peripheral area R-NAA. The second active area R-AA may be an area activated according to an electrical signal. The second active area R-AA may be an area where an image is displayed and various types of external inputs may be detected.

The second peripheral area R-NAA may be adjacent to the second active area R-AA. The light transmittance of the second peripheral area R-NAA may be lower than the light transmittance of the second active area R-AA. The second peripheral area R-NAA may have a predetermined color. The second peripheral area R-NAA may at least partially surround the second active area R-AA. For example, the second peripheral area R-NAA may completely surround the second active area R-AA. The electronic apparatus EA may further include a sub-area, in which an electronic module including various configurations is disposed, on the second display surface RS, and is not limited to any one embodiment.

Referring to FIG. 4, the electronic apparatus EA according to an embodiment of the present invention may be folded based on a second folding axis FX2 extended in the first direction DR1. The electronic apparatus EA may be folded based on the second folding axis FX2 and transformed into an out-folding state so that the first display surface FS is exposed to the outside. For example, the first non-folding area NFA1 and the second non-folding area NFA2 may face in opposite directions with respect to each other. In an embodiment of the present invention, the electronic apparatus EA may be configured such that the in-folding or out-folding operation is mutually repeated from the unfolding operation, but an embodiment of the present invention is not limited thereto.

In FIGS. 1 to 4, folding is illustrated based on one folding axis FX1 or FX2, but the number of folding axes and the number of non-folding areas according to the folding axis in the electronic apparatus EA according to an embodiment of the present invention are not limited thereto. For example, the electronic apparatus may be folded based on multiple folding axes so that a portion of each of the first display surface FS and the second display surface RS faces each other. In addition, the first and second folding axes FX1 and FX2 are illustrated as being parallel to the long sides of the electronic apparatus EA, but an embodiment of the present invention is not limited thereto, and the first and second folding axes FX1 and FX2 may be parallel to the short sides of the electronic apparatus EA.

In the electronic apparatus EA, each of the first non-folding area NFA1 and the second non-folding area NFA2 may be defined as a portion having display surfaces FS and RS, parallel to a plane that is defined by the first directional axis DR1 and the second directional axis DR2 in a folded state, as illustrated in FIG. 3, and the folding area FA may be defined as an area between the first non-folding area NFA1 and the second non-folding area NFA2. The folding area FA may include a curved portion that is bent to have a predetermined curvature in a folded state.

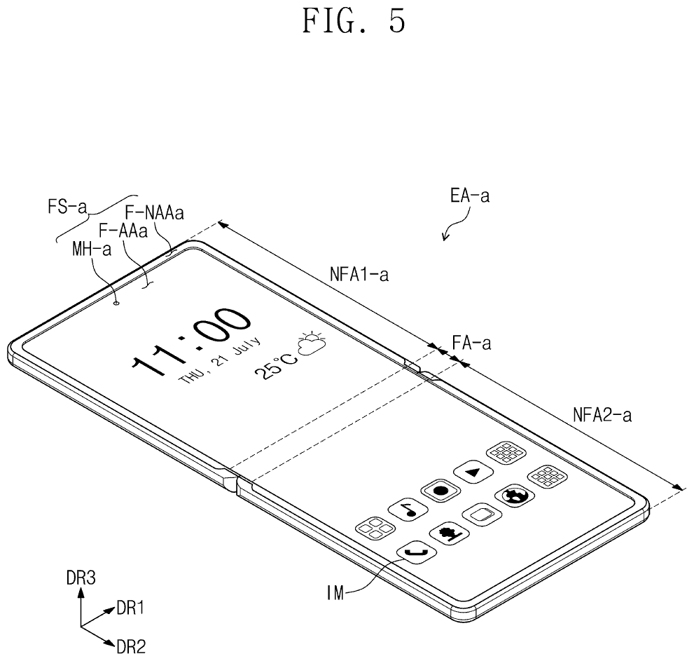

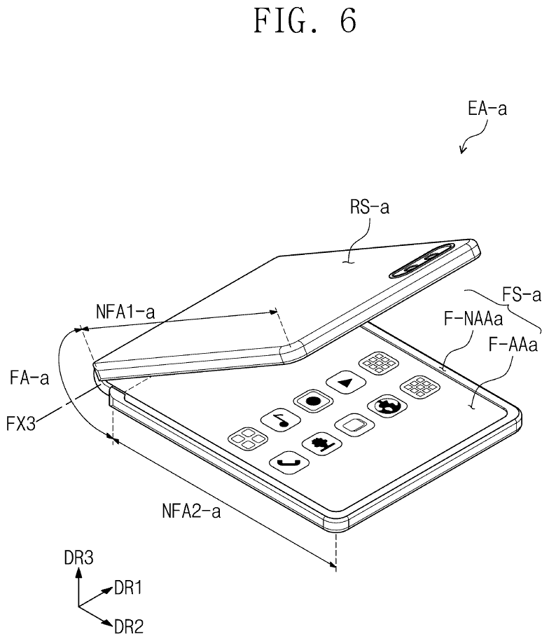

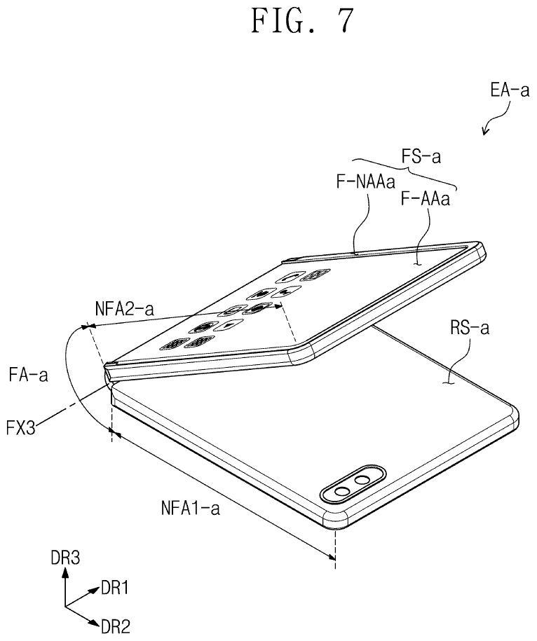

FIGS. 5 to 7 are perspective views illustrating an electronic apparatus EA-a according to an embodiment of the present invention. FIG. 5 is a perspective view illustrating an unfolded state of the electronic apparatus EA-a. FIGS. 6 and 7 are perspective views illustrating a folding operation of the electronic apparatus EA-a. FIG. 6 is a perspective view illustrating an in-folding operation of the electronic apparatus EA-a illustrated in FIG. 5. FIG. 7 is a perspective view illustrating an out-folding operation of the electronic apparatus EA-a illustrated in FIG. 5.

The electronic apparatus EA-a may be folded based on a third folding axis FX3 that is parallel to the first directional axis DR1. Referring to FIGS. 6 and 7, the extending direction of the third folding axis FX3 may be parallel to the extending direction of a short side of the electronic apparatus EA-a.

The electronic apparatus EA-a may be divided into a folding area FA-a, a first non-folding area NFA1-a that is adjacent to one side of the folding area FA-a, and a second non-folding area NFA2-a that is adjacent to the other side of the folding area FA-a. The first non-folding area NFA1-a and the second non-folding area NFA2-a may be spaced apart from each other with the folding area FA-a therebetween.

The folding area FA-a may be an area where the electronic apparatus EA-a is folded based on the third folding axis FX3. If the electronic apparatus EA-a is folded, the folding area FA-a may have a predetermined curvature and a radius of curvature. The first non-folding area NFA1-a and the second non-folding area NFA2-a face each other, and the electronic apparatus EA-a may be in-folded so that the display surface FS-a is not exposed to the outside.

Referring to FIG. 5, in an embodiment of the present invention, the electronic apparatus EA-a may be visible to the user in an unfolded state (i.e., in a not folded state) through a display surface FS-a. As described with reference to FIGS. 1 to 4, the display surface FS-a of the electronic apparatus EA-a may include an active area F-AAa, a peripheral area F-NAAa, and a sub-area MH-a. The active area F-AAa may be an area where an image IM is displayed and various forms of external inputs may be detected.

Referring to FIG. 6, a back RS-a may be visible to the user when the electronic apparatus EA-a, according to an embodiment of the present invention, is in an in-folded state. For example, the back RS-a may function as a second display surface that displays a video or an image. In addition, the back RS-a may also be provided with a sub-area in which electronic modules including various configurations are disposed.

Referring to FIG. 7, the electronic apparatus EA-a may be folded based on the third folding axis FX3 and transformed into an out-folding state in which one area of the back RS-a, overlapping with the first non-folding area NFA1-a, and the other area of the back RS-a, overlapping with the second non-folding area NFA2-a, face each other. For example, when the electronic apparatus EA-a is in the out-folding state, the first non-folding area NFA1-a and the second non-folding area NFA2-a may face in opposite directions with respect to each other.

FIG. 8 is an exploded perspective view of the electronic apparatus EA illustrated in FIG. 1. Hereinafter, the description of the electronic apparatus EA may be equally applied to the electronic apparatus EA-a illustrated in FIGS. 5 to 7.

FIG. 8 is an exploded perspective view illustrating the electronic apparatus EA according to an embodiment of the present invention. Referring to FIG. 8, the electronic apparatus EA may include an electronic module ELM and a display device DD. In addition, the electronic apparatus EA may further include a housing HAU. In an embodiment of the present invention, the display device DD may include a display module DM and a protective member RM disposed on the display module DM. The display device DD may have a module area DM-MH provided therein, and the electronic module ELM may be disposed to correspond to the module area DM-MH.

The protective member RM may be disposed on the uppermost part of the electronic apparatus EA. For example, the protective member RM may be a front surface of the electronic apparatus EA. An image IM (FIG. 1) produced from the display module DM may be provided to a user by passing through the protective member RM. The protective member RM may be folded based on at least one of the folding axes FX1 and FX2 (FIGS. 2 and 4). In an embodiment of the present invention, the protective member RM may exhibit characteristics of preventing damage such as cracks during low-curvature folding and facilitating repetition of folding and unfolding. The low-curvature folding may mean folding to have a small radius of curvature of about 2.0 mm or less or about 1.5 mm or less. Accordingly, the display device DD including the protective member RM, according to an embodiment of the present invention, and the electronic apparatus EA including the same may exhibit increased reliability.

The display device DD may further include an upper adhesive layer AP-R. The upper adhesive layer AP-R may be disposed between the display module DM and the protective member RM. The protective member RM and the display module DM may be combined to each other through the upper adhesive layer AP-R. The upper adhesive layer AP-R may include a pressure sensitive adhesive (PSA), an optically clear adhesive film (OCA), or an optically clear adhesive resin layer (OCR). However, this is an illustration and an embodiment of the present invention is not limited thereto. Unlike the drawing, the upper adhesive layer AP-R may be omitted.

The display module DM may display an image according to an electrical signal and transmit/receive information about an external input. A display area DM-DA and a non-display area DM-NDA may be provided in the display module DM. In addition, a module area DM-MH may be provided in the display module DM.

The display area DM-DA may be defined as an area that emits an image that is provided from the display module DM. The display area DM-DA of the display module DM may correspond to at least a portion of the first active area F-AA (FIG. 1).

A driving circuit or driving wiring for driving the display area DM-DA may be disposed in the non-display area DM-NDA. The non-display area DM-NDA may be adjacent to the display area DM-DA. For example, the non-display area DM-NDA may at least partially surround the display area DM-DA. However, this is an illustration, and the non-display area DM-NDA may be defined in various shapes and is not limited to any one embodiment.

The module area DM-MH may correspond to the sub-area MH illustrated in FIG. 1. An optical signal may move to the module area DM-MH. The module area DM-MH may be disposed within the display area DM-DA. However, this is an illustration, and is not limited to any one embodiment.

The electronic module ELM may be disposed to correspond to the module area DM-MH. The electronic module ELM may be an electronic component that outputs and/or receives an optical signal. The electronic module ELM may include a camera module and/or a proximity sensor. The camera module may capture an external image through the module area DM-MH.

The display module DM may include a folding display part FP-D and non-folding display parts NFP1-D and NFP2-D. The folding display part FP-D may correspond to the folding area FA of the electronic apparatus EA (FIG. 1), and the non-folding display parts NFP1-D and NFP2-D may correspond to the non-folding areas NFA1 and NFA2 of the electronic apparatus EA (FIG. 1).

The folding display part FP-D may fold along on the folding axes FX1 and FX2 (FIG. 2 and FIG. 4). The non-folding display parts NFP1-D and NFP2-D may include a first non-folding display part NFP1-D and a second non-folding display part NFP2-D. The first non-folding display part NFP1-D and the second non-folding display part NFP2-D may be spaced apart from each other in the second direction DR2 with the folding display part FP-D interposed therebetween. The first non-folding display part NFP1-D may be a part corresponding to the first non-folding area NFA1 (FIG. 1). The second non-folding display part NFP2-D may be a part corresponding to the second non-folding area NFA2 (FIG. 1).

A housing HAU may include a material having relatively high rigidity. For example, the housing HAU may include a plurality of frames and/or plates composed of glass, plastic, or metal. The housing HAU may provide a predetermined receiving space. The display module DM may be accommodated within the receiving space and protected from external impact by the housing HAU.

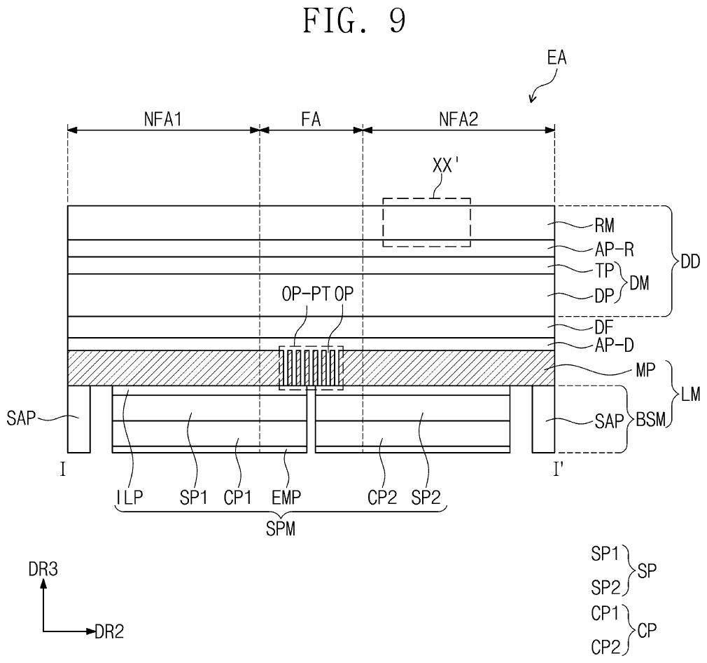

FIG. 9 is a cross-sectional view illustrating a portion corresponding to the line I-I′ shown in FIG. 8. FIG. 9 may be a cross-sectional view illustrating an electronic apparatus EA according to an embodiment of the present invention. In FIG. 9, the housing HAU (FIG. 8) is omitted for convenience of explanation.

Referring to FIG. 9, the electronic apparatus EA may further include a lower module LM, a lower adhesive layer AP-D, and a lower protective film DF. The lower module LM, the lower adhesive layer AP-D, and the lower protective film DF may be disposed between the display device DD and the housing HAU (FIG. 8).

The lower module LM may be disposed under the display module DM. The lower module LM may include a support plate MP and a lower support member (e.g., layer) BSM. The lower module LM illustrated in FIG. 9 is an example configuration, and the combination of the configurations included in the lower module LM in the electronic apparatus EA of an embodiment of the present invention may be changed depending on the size of the electronic apparatus EA, the shape of the electronic apparatus EA, or the operating characteristics of the electronic apparatus EA.

The support plate MP may include a metal material or a polymer material. For example, the support plate MP may be formed by including stainless steel, aluminum, or an alloy thereof. In addition, the support plate MP may be formed of a polymer material. A plurality of openings OP may be defined in the support plate MP. The support plate MP may include an opening pattern OP-PT in which a plurality of openings OP are defined. The opening pattern OP-PT may be formed in the folding area FA.

The lower support member BSM may include a support member SPM and a charging part SAP. On the plane, the support member SPM may be configured to overlap most of the area of the display module DM. The charging part SAP may be configured to be disposed on the outside of the support member SPM and overlap the outside of the display module DM. For example, the charging part SAP may be disposed around a perimeter of the support member SPM, from a plan view. For example, the charging part SAP may overlap a peripheral region of the display module DM.

The support member SPM may include at least one of a support layer SP, a cushion layer CP, a shield layer EMP, and an interlayer bonding layer ILP. The configuration of the support member SPM illustrated in FIG. 9 is an illustration, and an embodiment of the present invention is not limited thereto. For example, some of the support layer SP, the cushion layer CP, the shield layer EMP, and the interlayer bonding layer ILP may be omitted, or the stacking order may be changed to a different order from the order that is illustrated in FIG. 9, or an additional configuration other than the illustrated configuration may be further included in the support member SPM. For example, another layer may be included in the support member SPM.

The support layer SP may include a metal material or a polymer material. The support layer SP may be disposed under the support plate MP. For example, the support layer SP may be a thin film including a metal substrate. The support layer SP may include a first sub-support layer SP1 and a second sub-support layer SP2 that are spaced apart from each other in the second direction DR2. The space between the first sub-support layer SP1 and the second sub-support layer SP2 may be in an area corresponding to the folding axes FX1 and FX2 (FIGS. 2 and 4). The support layer SP may be provided as the first sub-support layer SP1 and the second sub-support layer SP2 that are spaced apart from each other in the folding area FA, thereby increasing the electronic apparatus's EA ability to fold more effectively.

The cushion layer CP may be disposed under the support layer SP. The cushion layer CP may prevent the support plate MP from experiencing a pressing effect or undergoing plastic deformation due to an external impact and/or a force. For example, the cushion layer CP may absorb the force from an accidental drop or a heavy object pressing against the electronic apparatus EA, preventing dents or permanent warping of the support plate MP. The cushion layer CP may increase the impact resistance of the electronic apparatus EA. For example, the cushion layer CP may include an elastomer such as a sponge, foam, or urethane resin. In addition, the cushion layer CP may be formed by including at least one of an acrylic polymer, a urethane-based polymer, a silicone-based polymer, and an imide-based polymer. However, this is an illustration, and an embodiment of the present invention is not limited thereto.

The cushion layer CP may include a first sub-cushion layer CP1 and a second sub-cushion layer CP2 that are spaced apart from each other in the second direction DR2. The first sub-cushion layer CP1 and the second sub-cushion layer CP2 may be spaced apart from each other at a portion corresponding to the folding axes FX1 and FX2 (FIGS. 2 and 4). For example, the space between the first sub-cushion CP1 and the second sub-cushion CP2 may be positioned to correspond to the folding axes FX1 and FX2. The cushion layer CP may improve the folding characteristics of the electronic apparatus EA by providing the first sub-cushion layer CP1 and the second sub-cushion layer CP2 to be spaced apart in the folding area FA.

The shielding layer EMP may be an electromagnetic shielding layer and/or a heat dissipation layer. For example, the shielding layer EMP may be a single layer or a multilayer structure. In addition, the shielding layer EMP may function as a bonding layer.

The interlayer bonding layer ILP may bond the components of the support plate MP and the support member SPM to each other. The interlayer bonding layer ILP may be provided in the form of a bonding resin layer or an adhesive tape. In FIG. 9, the interlayer bonding layer ILP is illustrated as being provided as two components that are spaced apart in an area corresponding to the folding axes FX1 and FX2 (FIGS. 2 and 4), but an embodiment of the present invention is not limited thereto. Unlike the drawing, the interlayer bonding layer ILP may be provided as one layer that is not spaced apart in an area corresponding to the folding axes FX1 and FX2 (FIGS. 2 and 4).

The charging part SAP may be disposed on the outside of the support layer SP and the cushion layer CP. The charging part SAP may be disposed between the support plate MP and the housing HAU (FIG. 8). The charging part SAP may fill the space between the support plate MP and the housing HAU (FIG. 8) and may fix the support plate MP. For example, the charging part SAP may be disposed between the housing HAU and the support plate MP in a third direction DR3.

The lower protective film DF may be disposed between the display module DM and the support plate MP. The lower protective film DF may be disposed under the display module DM to protect the back of the display module DM. However, the present inventive concept is not limited thereto, and for example, the lower protective film DF may be disposed on an upper surface of the display module DM. The lower protective film DF may be disposed above the support plate MP. The lower protective film DF may include a polymer material. For example, the lower protective film DF may be a polyimide film or a polyethylene terephthalate film. However, this is an illustration, and the lower protective film DF is not limited thereto.

A lower adhesive layer AP-D may be disposed between the support plate MP and the lower protective film DF. The support plate MP and the lower protective film DF may be combined through the lower adhesive layer AP-D. The lower adhesive layer AP-D may include, for example, a pressure sensitive adhesive (PSA), an optically clear adhesive film (OCA), or an optically clear adhesive resin layer (OCR). However, this is an illustration, and an embodiment of the present invention is not limited thereto. Unlike the drawing, the lower adhesive layer AP-D may be omitted.

The display module DM may include a display panel DP and an input sensing part TP disposed on the display panel DP. The display panel DP may be configured to produce an image. The display panel DP according to an embodiment of the present invention may be folded based on the folding axes FX1 and FX2 (FIGS. 2 and 4).

The input sensing part TP may detect an external input, change it into a predetermined input signal, and provide the input signal to the display panel DP through a processor. The processor interprets and processes the input signal, ensuring it is correctly mapped to the intended response or action on the display panel. For example, the input sensing part TP may be a touch detection part that detects a touch. The input sensing part TP may recognize a direct touch of a user, an indirect touch of a user, a direct touch of an object, or an indirect touch of an object.

The input sensing part TP may detect at least one of a position of a touch applied from the outside and a strength (pressure) of the touch. In an embodiment of the present invention, the input sensing part TP may have various structures or be composed of various materials, and is not limited to any one embodiment. For example, the input sensing part TP may detect an external input in a capacitive manner. The display panel DP may receive an input signal from the input sensing part TP and generate an image corresponding to the input signal.

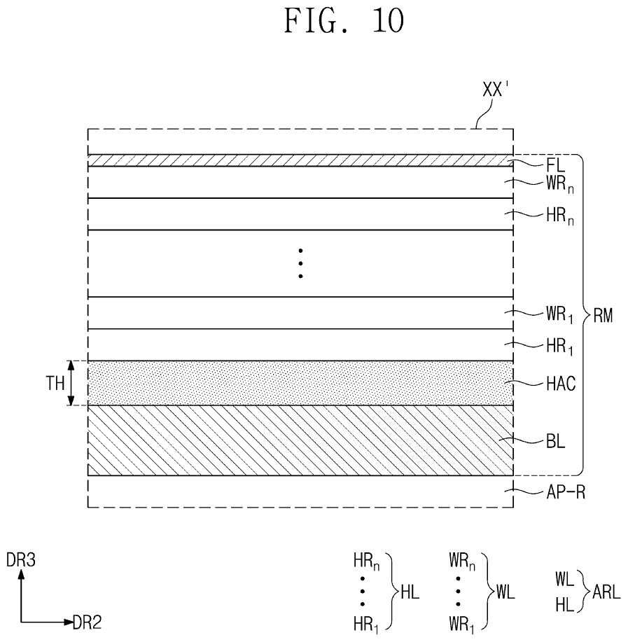

FIG. 10 is an enlarged cross-sectional view illustrating an area XX′ in FIG. 9. FIG. 10 may be a cross-sectional view illustrating the configuration of the protective member RM.

Referring to FIG. 10, the protective member RM may include a protective base layer BL, a hard coating layer HAC disposed on the protective base layer BL, and an antireflection layer ARL disposed on the hard coating layer HAC. In addition, the protective member RM may further include a functional layer FL disposed on the antireflection layer ARL.

The protective base layer BL may be a member providing a base surface on which the hard coating layer HAC and the antireflection layer ARL are disposed. For example, the protective base layer BL may be a polymer film having flexibility. The protective base layer BL may include at least one of, for example, polyethylene terephthalate, polyimide, polyacrylate, polymethyl methacrylate, polycarbonate, polyethylene naphthalate, polyvinylidene chloride, polyvinylidene difluoride, polystyrene, or an ethylene vinyl alcohol copolymer. The thickness of the protective base layer BL may be about 65 μm. However, this is an illustration, and the thickness of the protective base layer BL is not limited thereto.

The functional layer FL may include a polymer film. The functional layer FL may include an anti-fingerprint coating agent, an antistatic agent, or the like. Unlike the drawing, the functional layer FL may be omitted.

The thickness TH of the hard coating layer HAC may be about 1 μm to about 8 μm. For example, the thickness TH of the hard coating layer HAC may be about 3 μm to about 5 μm. A hard coating layer HAC having a thickness of less than about 1 μm is too thin to exhibit sufficient hardness and durability. A hard coating layer HAC having a thickness that is greater than about 8 μm increases the thickness of the display device due to the thick thickness, and the repetition of folding and unfolding might not be easy to perform. A hard coating layer HAC having a thickness TH of about 1 μm to about 8 μm may exhibit excellent hardness and excellent durability without increasing the thickness of the display device DD (FIG. 9), and may exhibit characteristics that facilitate easy repetition of folding and unfolding.

In an embodiment of the present invention, the hard coating layer HAC may include a polymer derived from a coating composition. The hard coating layer HAC may be formed by curing the coating composition. The coating composition is cured through a cationic curing process, and may exhibit excellent coating properties. The cationic curing process may minimize (or prevent) curing inhibition due to oxygen. In addition, the coating composition according to an embodiment of the present invention may be cured by the cationic curing process, and may exhibit low shrinkage during curing and excellent adhesion after curing.

For example, a protective base layer BL may be prepared, a coating composition may be provided on the protective base layer BL, and a hard coating layer HAC may be formed by emitting light to the coating composition that is provided on the protective base layer BL. Thereafter, an antireflection layer ARL may be provided on the hard coating layer HAC. The member on which the coating composition is provided is not limited to the protective base layer BL, and the coating composition may be cured after being provided on a temporary substrate, or the like. In this case, the hard coating layer HAC formed by curing the coating composition may be removed from the temporary substrate after curing, and provided on the protective base layer BL. The temporary substrate is not limited to any one embodiment as long as it is a substrate from which the hard coating layer HAC is easily detachable.

A coating composition forming the hard coating layer HAC may include, for example, a silsesquioxane-based resin, an oxetane-based resin, the photopolymerization initiator, and silica nanoparticles. In an embodiment of the present invention, a hard coating layer HAC formed from the coating composition including the silsesquioxane-based resin, the oxetane-based resin, the photopolymerization initiator, and the silica nanoparticles may exhibit high elongation and may be easily subjected to low-curvature folding and repetition of folding and unfolding. In the description, the silsesquioxane-based resin means one containing a silsesquioxane functional group, and the oxetane-based resin means one containing an oxetane functional group.

Based on 100 wt % of the total weight of the coating composition, the first weight of the silica nanoparticles may be about 3 wt % to about 5 wt %. Based on 100 wt % of the total weight of the coating composition, a hard coating layer formed from a coating composition containing silica nanoparticles having a weight of less than about 3 wt %, exhibits relatively low hardness, resulting in reduced durability. Based on 100 wt % of the total weight of the coating composition, a coating composition including silica nanoparticles having a weight of greater than about 5 wt % causes particle agglomeration or the like, and fails to form a hard coating layer having uniform hardness. The hard coating layer HAC of an embodiment of the present invention formed from the coating composition including silica nanoparticles having a weight of about 3 wt % to about 5 wt % based on 100 wt % of the total weight of the coating composition may exhibit excellent hardness.

The diameter of the silica nanoparticles may be about 20 nm to about 60 nm. The hard coating layer HAC of an embodiment of the present invention formed from the coating composition including silica nanoparticles having a diameter of about 20 nm to about 60 nm and satisfying the weight range described above (i.e., about 3 wt % to about 5 wt %) may exhibit excellent hardness and excellent wear resistance.

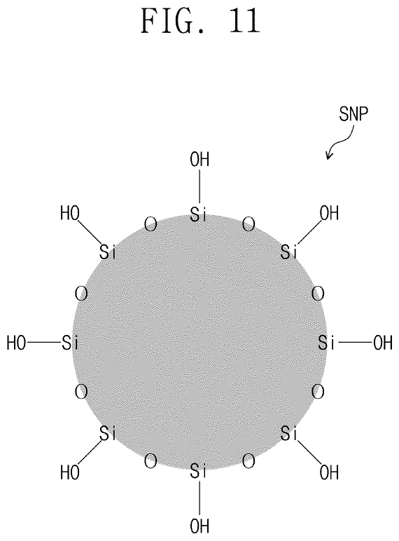

FIG. 11 is a drawing illustrating, as an example, a silica nanoparticle SNP according to an embodiment of the present invention. Referring to FIG. 11, a silica nanoparticle SNP may include silicon atoms, oxygen atoms, and hydroxyl groups (—OH). In the silica nanoparticle SNP, the silicon atoms (Si) and the oxygen atoms (O) may exist on the surface, and the hydroxyl groups may be bonded to the silicon atoms on the surface. In FIG. 11, the number/position of silicon atoms, the number/position of oxygen atoms, and the number/position of hydroxyl groups are for illustrating an example, and an embodiment of the present invention is not limited thereto.

In the coating composition according to an embodiment of the present invention, the hydroxyl groups of the silica nanoparticles (SNPs) may be partially bonded to a silsesquioxane-based resin or an oxetane-based resin. Accordingly, if the coating composition is cured, the bonding strength of the silsesquioxane-based resin and the oxetane-based resin may be increased, and the hard coating layer HAC formed from the coating composition according to an embodiment of the present invention may exhibit high toughness characteristics.

The silsesquioxane-based resin may include a partial cage structure, a ladder structure, a random structure, and/or a cage structure. The silsesquioxane-based resin may include 7 or 8 siloxane units. For example, the silsesquioxane-based resin may include a partial cage structure and 7 siloxane units. In addition, the silsesquioxane-based resin may include a cage structure and 8 siloxane units. For example, the partial cage structure may be represented by Formula P-1 below, and the siloxane unit may be represented by Formula S-1 below.

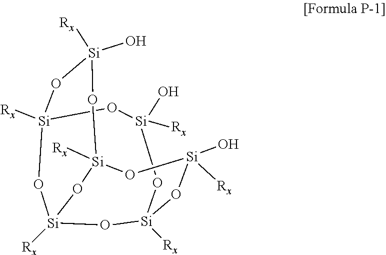

In Formula P-1, multiple Rx may each independently be a hydrogen atom, an alkyl group having 1 to 60 carbon atoms, an alkenyl group having 2 to 60 carbon atoms, an alkoxy group having 1 to 60 carbon atoms, or an aryl group having 6 to 60 ring-forming carbon atoms.

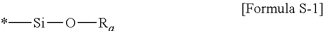

In Formula S-1, Ra may be a hydrogen atom, an alkyl group having 1 to 60 carbon atoms, an alkenyl group having 2 to 60 carbon atoms, an alkoxy group having 1 to 60 carbon atoms, or an aryl group having 6 to 60 ring-forming carbon atoms. A hard coating layer HAC including a polymer derived from a coating composition including a silsesquioxane-based resin having 7 or 8 siloxane units may exhibit increased hardness and increased flexibility.

The silsesquioxane-based resin may include at least one of, for example, a T-type silsesquioxane unit, a D-type silsesquioxane unit, or an M-type silsesquioxane unit. The T-type silsesquioxane unit may be represented by Formula A-1 or Formula A-2 that are provided below. The D-type silsesquioxane unit may be represented by Formula B-1 or Formula B-2 below. The M-type silsesquioxane unit may be represented by any one of Formulas C-1 to C-4 below. In Formulas A-1, A-2, B-1, B-2, and C-1 to C-4, R₁ to R₂₀ may each independently be a hydrogen atom, an alkyl group having 1 to 60 carbon atoms, an alkenyl group having 2 to 60 carbon atoms, an alkoxy group having 1 to 60 carbon atoms, or an aryl group having 6 to 60 ring-forming carbon atoms.

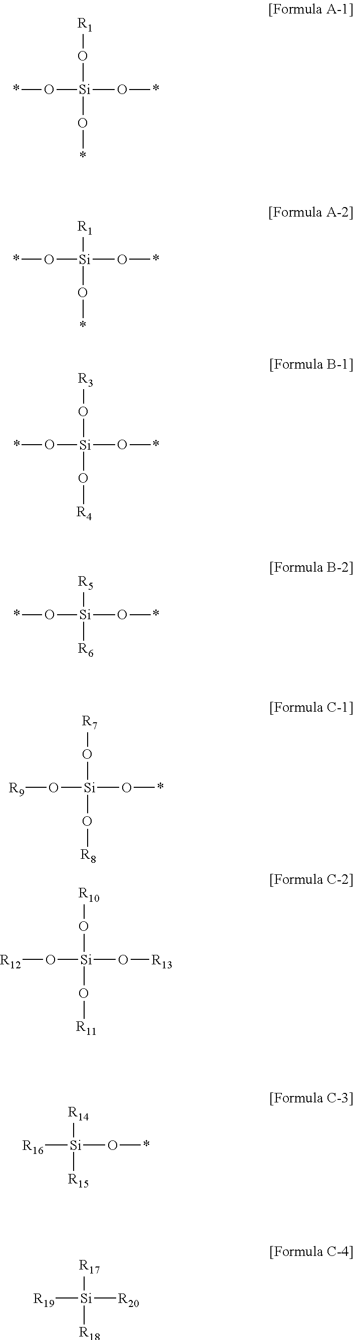

The oxetane-based resin may include a moiety of 1,4-bis[(3-ethyl-3-oxetanylmethoxy)methyl]benzene. The oxetane-based resin may include a moiety represented by Formula 1 that is below.

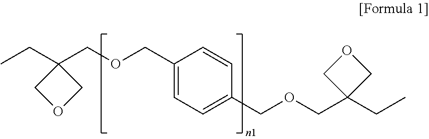

In Formula 1 above, n1 may be an integer of 3 to 100. For example, n1 may be 3. A hard coating layer formed from a coating composition including a moiety in which n1 is 1 or 2, exhibits low flexibility, and cracks may occur during low-curvature folding. In addition, repetition of folding and unfolding might not be easy. A hard coating layer formed from a coating composition including a moiety in which n1 is 3 or more, may exhibit increased flexibility, prevent damage during low-curvature folding, and exhibit easy characteristics in repetition of folding and unfolding.

For example, the moiety represented by Formula 1 may be combined with a silsesquioxane-based resin having a partial cage structure and including seven siloxane units. In addition, the moiety represented by Formula 1 may be combined with a silsesquioxane-based resin having a cage structure and including eight siloxane units, and each of the eight siloxane units may constitute a T-type silsesquioxane unit. Accordingly, the hard coating layer HAC formed from the coating composition exhibits increased flexibility, so that cracks and other damages are prevented even during low-curvature folding, and folding and unfolding may be easily repeated.

The hard coating layer HAC formed by combining the moiety represented by Formula 1 and a silsesquioxane-based resin having a partial cage structure and seven siloxane units may exhibit peaks at wavenumbers of about 1066 cm¹ and about 2138 cm¹ in an infrared spectrum (IR Spectrum) according to infrared spectroscopy. The Exhibition of a peak at a wavenumber of about 1066 cm¹ means that a moiety of Si—O—Si is included, and the exhibition of a peak at a wavenumber of about 2138 cm¹ means that a moiety of Si—H is included. In addition, the hard coating layer HAC according to an embodiment of the present invention may be observed to have a peak of Si(OSi≡)₄ at about-107.6 ppm in the Si NMR spectrum, and a peak of Si—H at about 4.7 ppm in the H NMR spectrum.

Based on 100 wt % of the total weight of the coating composition, the sum of the second weight of the silsesquioxane-based resin and the third weight of the oxetane-based resin may be about 93 wt % to about 95 wt %. The silsesquioxane-based resin may exhibit high hardness while increasing flexibility. The oxetane-based resin may increase flexibility. Accordingly, a hard coating layer HAC formed from a coating composition in which the sum of the second weight of the silsesquioxane-based resin and the third weight of the oxetane-based resin satisfies the above-mentioned range (i.e., about 93 wt % to about 95 wt %) based on 100 wt % of the total weight of the coating composition may exhibit increased hardness and increased flexibility. Accordingly, the hard coating layer HAC may exhibit characteristics in which cracks or the like do not occur during low-curvature folding and easy repetition of folding and unfolding.

In the coating composition for forming the hard coating layer HAC, the weight of the photopolymerization initiator may be about 2 wt % or less based on 100 wt % of the total weight of the coating composition. In the coating composition for forming the hard coating layer HAC, the weight of the photopolymerization initiator may be greater than about 0 wt % to about 2 wt % based on 100 wt % of the total weight of the coating composition. In a coating composition for forming a hard coating layer HAC, the photopolymerization initiator may include a triarylsulfonium hexafluoroantimonate salt. A hard coating layer HAC formed from a coating composition including a triarylsulfonium hexafluoroantimonate salt may have increased oxidation ability and may be prevented from being deformed even if exposed to oxygen.

The photopolymerization initiator may include, for example, triarylsulfonium hexafluoroantimonate salts mixed, which is a mixed salt of triarylsulfonium ion and hexafluoroantimonate ion. The triarylsulfonium hexafluoroantimonate salt may be represented by Formula E-1 that is provided below. In Formula E-1, S⁺ of triarylsulfonium may make an ionic bond to Sb⁻ of hexafluoroantimonate.

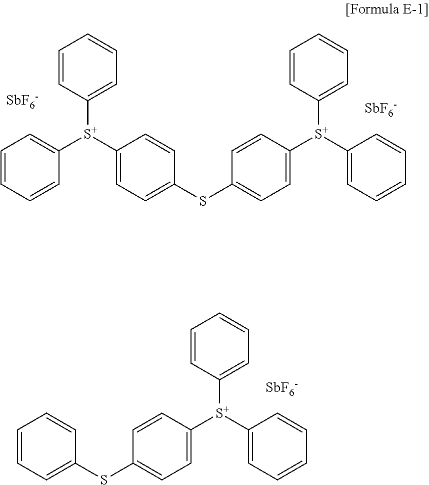

The coating composition for forming the hard coating layer HAC may further include a solvent. In the coating composition, the solvent may include at least one of, for example, 1-methoxy-2-methyl-2-propanol, 1-methoxy-2-propanol, or 2-butanone.

In addition, the coating composition for forming a hard coating layer HAC may further include an additive within a range that does not inhibit the physical properties of the hard coating layer HAC. The additive may include a leveling agent, a dispersing agent, or the like, but these are illustrations, and the additive may include additives known in the art without limitation. For example, based on 100 wt % of the total weight of the coating composition, the weight of the additive may be about 2 wt %.

A hard coating layer HAC formed from a coating composition according to an embodiment of the present invention may have a specular component included (SCI) reflectivity of about 0.5% to about 1.5%. A hard coating layer HAC having an SCI reflectivity of about 0.5% to about 1.5% may increase the display quality of a display device DD (FIG. 9) due to the small reflectivity.

The hard coating layer HAC formed from the coating composition according to an embodiment of the present invention may have a hardness of about 0.22 GPa to about 0.32 GPa and an elastic modulus of about 2.78 GPa to about 3.78 GPa. The hardness and elastic modulus may be measured by providing a hard coating layer HAC having a thickness TH of about 5 μm on a protective base layer BL including polyethylene terephthalate and using a nanoindenter from Bruker Co. at an indentation depth of about 200 nm. A hard coating layer HAC having a hardness and an elastic modulus satisfying the above-mentioned ranges may exhibit increased reliability.

A hard coating layer HAC formed from a coating composition including, for example, a silsesquioxane-based resin, an oxetane-based resin, a photopolymerization initiator, and silica nanoparticles, each of which satisfies the weight range described above, may have a crack strain of about 8% or more. A hard coating layer HAC having a crack strain of about 8% or more may exhibit characteristics of preventing damage during low-curvature folding and facilitating repetition of folding and unfolding due to excellent flexibility.

In addition, a hard coating layer HAC formed from a coating composition including, for example, a silsesquioxane-based resin, an oxetane-based resin, a photopolymerization initiator, and silica nanoparticles, each of which satisfies the weight range described above, may have a water contact angle of about 100° or more before an eraser wear resistance evaluation, and a water contact angle of about 95° or less after the evaluation. In this case, the eraser wear resistance evaluation may be performed 5,000 times back and forth with a load of about 1 kgf using an eraser dedicated for wear resistance testing. A hard coating layer HAC satisfying the above-mentioned range of the water contact angle before and after the eraser wear resistance evaluation may exhibit excellent wear resistance.

Referring to FIG. 10 again, the antireflection layer ARL may include a high refractive index layer HL and a low refractive index layer WL disposed on the high refractive index layer HL. The antireflection layer ARL may be formed by a dry process. The high refractive index layer HL may include multiple high refractive index layers HR1, . . . . HRn. In other words, the high refractive index layer HL may be provided as multiple high refractive index layers HR1, . . . . HRn. The low refractive index layer WL may include multiple low refractive index layers WR1, . . . . WRn. In other words, the low refractive index layer WL may be provided as multiple low refractive index layers WR1, . . . . WRn. Here, n is an integer of 2 or more. The protective member RM, includes multiple high refractive index layers HR1, . . . HRn and multiple low refractive index layers WR1, . . . . WRn, exhibits low reflectivity, thereby increasing the display quality of the display device DD. The multiple high refractive index layers HR1, . . . . HRn and the multiple low refractive index layers WR1, . . . . WRn may be alternately disposed on the protective base layer BL. A functional layer FL may be disposed on the nth low refractive index layer WRn. For example, each of the high refractive index layer HL and the low refractive index layer WL may be provided as five layers.

The refractive index of the low refractive index layer WL may be about 1.3 to about 1.5. For example, the low refractive index layer WL may include silicon dioxide (SiO₂). However, this is an illustration, and the low refractive index layer WL may include a material with low refractive index characteristics known in the relevant technical field without limitation.

The refractive index of the high refractive index layer HL may be about 1.6 to about 2.5. The high refractive index layer HL may include, for example, niobium pentoxide (Nb₂O₅) and titanium dioxide (TiO₂). In the high refractive index layer HL, a ratio of the fourth weight to the fifth weight may be about 7:3 to about 9:1 based on the sum of the fourth weight of niobium pentoxide and the fifth weight of titanium dioxide. A member including niobium pentoxide has increased flexibility, and a member, which includes titanium dioxide, may exhibit high hardness. The high refractive index layer HL, which includes niobium pentoxide and titanium dioxide, and the fourth weight of niobium pentoxide and the fifth weight of titanium dioxide satisfies about 7:3 to about 9:1, may exhibit increased flexibility and increased hardness. Accordingly, the high refractive index layer HL may exhibit characteristics of low-curvature folding and easy repetition of folding and unfolding. A display device DD (FIG. 9) and an electronic apparatus EA (FIG. 9) including the high refractive index layer HL may exhibit increased reliability.

Table 1 below shows the configuration of the protective members of the Comparative Examples and the Example used in the evaluation of Table 2. In Table 1, the protective member of Example 1 is a protective member according to an embodiment of the present invention. Table 2 below shows the results of evaluating crack strain, wear resistance, and SCI reflectivity in the protective members of the Comparative Examples and the Example.

TABLE 1

| | Comparative | Comparative | Comparative | |
|---|---|---|---|---|
| | Example 1 | Example 2 | Example 3 | Example 1 |
| Protective | PET, 50 μm | PET, 50 μm | PET, 65 μm | PET, 65 μm |
| base layer | | | | |
| Hard coating | Composition 1 | Composition 1 | Composition 2 | Composition 3 |
| layer | | | | |
| Antireflection | ZrOₓ/SiOₓ | Nb₂O₅/SiO₂ | Nb₂O₅ and | Nb₂O₅ and |
| layer | (two layers) | (seven layers) | TiO₂/SiO₂ | TiO₂/SiO₂ |
| | | | (five layers) | (five layers) |
| | | | | (Nb₂O₅:TiO₂ = 9:1) |

In Table 1, the protective members of Comparative Examples 1 and 2 have a protective base layer thickness of about 50 μm, and the protective members of Comparative Example 3 and Example 1 have a protective base layer thickness of about 65 μm. The protective members of Comparative Examples 1 to 3 and Example 1 have a protective base layer including polyethylene terephthalate (PET).

In the protective members of Comparative Examples 1 and 2, the hard coating layer is formed from Composition 1, and Composition 1 includes an acrylic resin. The acrylic resin exhibits relatively low elongation. The hard coating layer of Comparative Example 3 is formed from Composition 2, and Composition 2 includes a silsesquioxane-based resin, an oxetane-based resin, and a photopolymerization initiator. Composition 2 does not include silica nanoparticles. The hard coating layer of Example 1 is formed from Composition 3, and Composition 3 includes a silsesquioxane-based resin, an oxetane-based resin, a photopolymerization initiator, and silica nanoparticles. Based on the total weight of 100 wt % of Composition 3, the weight of the silica nanoparticles is about 3 wt %. Composition 3 is a coating composition according to an embodiment of the present invention, satisfying the weight range of the silica nanoparticles described above (i.e., about 3 wt % to about 5 wt %).

The protective members of Comparative Examples 1 to 3 and Example 1 include high refractive index layers and low refractive index layers alternately disposed. In the protective member of Comparative Example 1, the antireflection layer is formed by a wet process, and each of the high refractive index layer and the low refractive index layer is provided in two layers. In the protective member of Comparative Example 1, the high refractive index layer includes zirconium oxide (ZrOₓ), and the low refractive index layer includes silicon oxide (SiOₓ).

In the protective member of Comparative Example 2, the antireflection layer is formed by a dry process, and each of the high refractive index layer and the low refractive index layer is provided in seven layers. In the protective member of Comparative Example 2, the high refractive index layer includes niobium pentoxide (Nb₂O₅), and the low refractive index layer includes silicon dioxide (SiO₂).

In the protective member of Comparative Example 3, the antireflection layer is formed by a dry process, and each of the high refractive index layer and the low refractive index layer is provided in five layers. In the protective member of Comparative Example 3, the high refractive index layer includes niobium pentoxide (Nb₂O₅) and titanium dioxide (TiO₂), and the low refractive index layer includes silicon dioxide (SiO₂). In the high refractive index layer, the ratio of the weight of niobium pentoxide to the weight of titanium dioxide is about 9:1 based on the sum of the weight of niobium pentoxide and the weight of titanium dioxide.

In the protective member of Example 1, the antireflection layer is formed by a dry process, and each of the high refractive index layer and the low refractive index layer is provided in five layers. In the protective member of Example 1, the high refractive index layer includes, for example, niobium pentoxide (Nb₂O₅) and titanium dioxide (TiO₂), and the low refractive index layer includes silicon dioxide (SiO₂). In the high refractive index layer, the ratio of the weight of the niobium pentoxide to the weight of the titanium dioxide is about 9:1 based on the sum of the weight of the niobium pentoxide and the weight of the titanium dioxide. That is, in Example 1, the weight of the niobium pentoxide and the weight of the titanium dioxide satisfy the weight range described above (i.e., about 7:3 to about 9:1).

In Table 2 below, the crack strain, wear resistance, and SCI reflectivity are evaluated by the methods below. Crack strain was measured using Instron's Universal Testing Machine (UTM), by fixing a protective member of 10 mm wide×60 mm long, pulling the protective member at a speed of about 50 mm/min, and then checking cracks. The wear resistance evaluation was conducted by comparing the water contact angle before and after the eraser wear resistance evaluation to see if specified criteria were met. The specified criteria were that the water contact angle before the evaluation was about 100° or higher and the water contact angle after the evaluation was about 95° or higher. The liquid used for the water contact angle evaluation was water. The eraser wear resistance evaluation was conducted using an industrial eraser from Munbangsau Co. with a protrusion of about 5 mm, and using a wear resistance tester from Daesung Precision Co. under the conditions of a load of about 1 kgf, a speed of about 50 rpm, and a reciprocating distance of about 15 mm. Afterwards, the contact angle was measured using a Kruss contact angle measuring device (Drop Shape Analysis System).

In the wear resistance in Table 2, “NG” means that it does not meet the given criteria, and “OK” means that it meets the given criteria. Comparative Examples 1 and 2 were not evaluated because the flexibility was very small and wear resistance evaluation was not possible.

The SCI reflectivity represents the SCI reflectivity for light with a wavelength of about 550 nm. The SCI reflectivity was measured in the reflection mode of a spectrophotometer CM-3700A from Konica Minolta Co., and was evaluated by attaching a black tape to one side of the PET of the protective member. The protective member of Comparative Example 3 showed an SCI reflectivity of about 0.61 to about 0.7, and the protective member of Example 1 showed an SCI reflectivity of about 0.56 to about 0.69.

TABLE 2

| | Comparative | Comparative | Comparative | |
|---|---|---|---|---|
| | Example 1 | Example 2 | Example 3 | Example 1 |
| Crack strain (%) | 4.5 | 2 | 16.0 | 12.5 |
| Wear resistance | — | — | NG | OK |
| SCI reflectivity | 1.33 | 0.25 | 0.61-0.7 | 0.56-0.69 |
| (%, @550 nm) | | | | |

Referring to Table 2, it can be found that, compared to Comparative Examples 1 and 2, Comparative Example 3 and Example 1 exhibit high crack strains, and the crack strains are about 8% or more. It can be found that Comparative Examples 2, Comparative Example 3, and Example 1 exhibit SCI reflectivity of about 0.5% to about 1.5%. It can be found that Comparative Example 3 and Example 1 exhibit SCI reflectivity of about 1.0% or less. It can be found that Example 1 satisfies the wear resistance criteria.

As described above, the protective member of Example 1 includes a hard coating layer, which is formed from the coating composition according to an embodiment of the present invention, and a high refractive index layer, which includes niobium pentoxide (Nb₂O₅) and titanium dioxide (TiO₂) satisfying the weight ratio described above. It can be found that the protective member of Example 1 includes a protective base layer having a greater thickness than the protective members of Comparative Examples 1 and 2, but exhibits a high crack strain value by including the hard coating layer according to an embodiment of the present invention. A high crack strain value means increased flexibility, and since increased flexibility is shown, low-curvature folding and repetition of folding and unfolding are easy. In addition, it can be found that the protective member of Example 1 is formed from the coating composition including silica nanoparticles and shows increased wear resistance. Accordingly, it can be found that the protective member including the hard coating layer and the high refractive index layer according to an embodiment of the present invention will show increased flexibility, increased wear resistance, and increased reflectivity.

As described above, in the protective members of Comparative Examples 1 and 2, the hard coating layer was formed from Composition 1 including an acrylic resin having a low elongation. Accordingly, the protective members of Comparative Examples 1 and 2 showed low crack strain.

As described above, the protective member of Comparative Example 3 was formed from Composition 2 that did not include silica nanoparticles. Accordingly, the protective member of Comparative Example 3 did not satisfy the predetermined standard in the wear resistance evaluation and showed poor wear resistance.

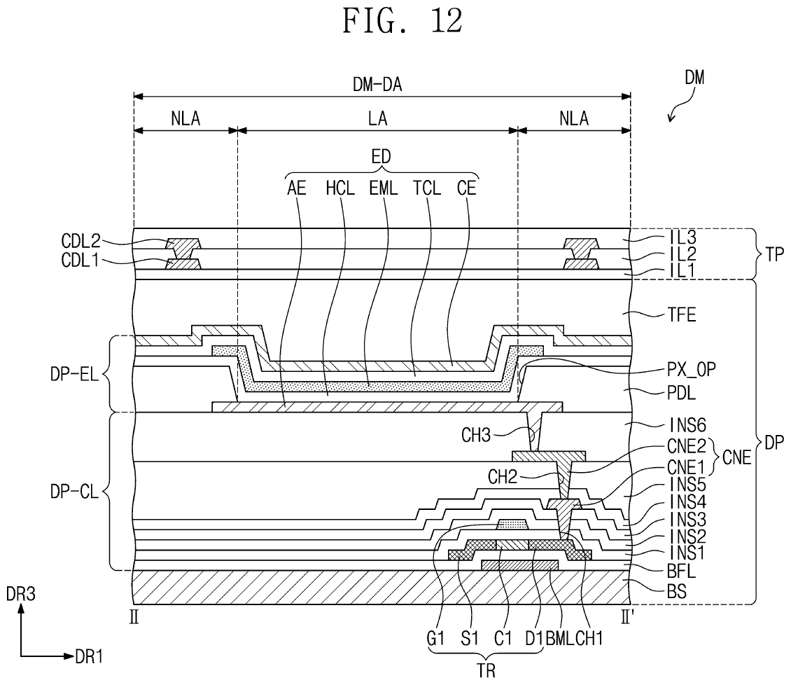

FIG. 12 is a cross-sectional view illustrating a portion corresponding to line II-II′ in FIG. 8. FIG. 12 may be a cross-sectional view specifically illustrating a display area DM-DA of a display module DM.

Referring to FIG. 12, a display panel DP may include a base substrate BS, a circuit layer DP-CL disposed on the base substrate BS, a display element layer DP-EL disposed on the circuit layer DP-CL, and an encapsulation layer TFE covering the display element layer DP-EL. The configuration of the display panel DP illustrated in FIG. 12 is an illustration, and the configuration of the display panel DP is not limited thereto.

The base substrate BS may provide a base surface on which the circuit layer DP-CL is disposed. The base substrate BS may be a flexible substrate capable of bending, folding, rolling, or the like. The base substrate BS may be a glass substrate, a metal substrate, a polymer substrate, or the like. However, an embodiment of the present invention is not limited thereto, and the base substrate BS may include an inorganic layer, an organic layer, or a composite material layer.

The base substrate BS may include a single layer or multiple layers. For example, the base substrate BS may include a first synthetic resin layer, multiple layers of an inorganic layer or a single layer, and a second synthetic resin layer disposed on the inorganic layer of multiple layers or a single layer. Each of the first synthetic resin layer and the second synthetic resin layer may include a polyimide-based resin. In addition, each of the first synthetic resin layer and the second synthetic resin layer may include at least one of an acrylic resin, a methacrylic-based resin, a polyisoprene-based resin, a vinyl resin, an epoxy-based resin, a urethane-based resin, a cellulose-based resin, a siloxane-based resin, a polyamide-based resin, or a perylene-based resin. In the description, the “˜”-based resin means a resin including a functional group of “˜˜.”

The display panel DP may include a transistor TR and a light emitting element ED. The transistor TR and the light emitting element ED may be disposed on the base substrate BS. In FIG. 12, one transistor TR is shown, but the display panel DP may include a plurality of transistors and at least one capacitor for driving the light emitting element ED.

The circuit layer DP-CL may include an insulating layer, a semiconductor pattern, a conductive pattern, a signal line, and the like. For example, the circuit layer DP-CL may include a switching transistor and a driving transistor for driving the light emitting element ED of the display element layer DP-EL.

The circuit layer DP-CL may include a shielding electrode BML, a transistor TR, a connection electrode CNE, and a plurality of insulating layers BFL and INS1 to INS6. The plurality of insulating layers BFL and INS1 to INS6 may include a buffer layer BFL and first to sixth insulating layers INS1 to INS6. However, the stacked structure of the circuit layer DP-CL shown in FIG. 12 is an illustration, and the stacked structure of the circuit layer DP-CL may be changed depending on the configuration of the display panel DP and the process of the circuit layer DP-CL, or the like.

The shielding electrode BML may be disposed on the base substrate BS. The shielding electrode BML may overlap the transistor TR. The shielding electrode BML may block light incident on the transistor TR from the lower portion of the display panel DP to protect the transistor TR. For example, the shielding electrode BML may be disposed below the transistor TR. The shielding electrode BML may include a conductive material. If a voltage is applied to the shielding electrode BML, the threshold voltage of the transistor TR disposed on the shielding electrode BML may be maintained. However, an embodiment of the present invention is not limited thereto, and the shielding electrode BML may be a floating electrode. The shielding electrode BML may be omitted.

The buffer layer BFL may be disposed on the base substrate BS to cover the shielding electrode BML. For example, the buffer layer BFL may be disposed between the shielding electrode BML and the transistor TR. The buffer layer BFL may include an inorganic layer. The buffer layer BFL may increase the bonding strength between a semiconductor pattern or conductive pattern disposed on the buffer layer BFL and the base substrate BS.

The transistor TR may include a source S1, a channel C1, a drain D1, and a gate G1. The source S1, the channel C1, and the drain D1 of the transistor TR may be formed in the semiconductor pattern. The semiconductor pattern of the transistor TR may include polysilicon, amorphous silicon, or a metal oxide, and any material having semiconductor properties may be applied without limitation and is not limited to any one of them.

The semiconductor pattern may include a plurality of areas that are distinguished by the size of the conductivity. Among the semiconductor patterns, areas doped with a dopant or have a metal oxide that is reduced may have high conductivity and may substantially serve as the source and drain electrodes of the transistor TR. Among the semiconductor patterns, the areas with high conductivity may correspond to the source S1 and drain D1 of the transistor TR. Among the semiconductor patterns, areas that are undoped or doped at a low concentration or have a metal oxide that is not reduced and thus have low conductivity may correspond to the channel C1 (or active) of the transistor TR.

The first insulating layer INS1 covers the semiconductor pattern of the transistor TR and may be disposed on the buffer layer BFL. The gate G1 of the transistor TR may be disposed on the first insulating layer INS1. On a plane, the gate G1 may overlap the channel C1 of the transistor TR. The gate G1 may function as a mask in the process of doping the semiconductor pattern of the transistor TR.

The second insulating layer INS2 covers the gate G1 and may be disposed on the first insulating layer INS1. The third insulating layer INS3 may be disposed on the second insulating layer INS2.

The connection electrode CNE may include a first connection electrode CNE1 and a second connection electrode CNE2 for electrically connecting the transistor TR and the light emitting element ED. However, the configuration of the connection electrode CNE for electrically connecting the transistor TR and the light emitting element ED is not limited thereto, and one of the first or second connection electrodes CNE1 or CNE2 may be omitted, or an additional connection electrode may be included.

The first connection electrode CNE1 may be disposed on the third insulating layer INS3. The first connection electrode CNE1 may be connected to the drain D1 through a first contact hole CH1 penetrating the first to third insulating layers INS1 to INS3. The fourth insulating layer INS4 may cover the first connection electrode CNE1 and may be disposed on the third insulating layer INS3. The fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 penetrating the fourth and fifth insulating layers INS4 and INS5. The sixth insulating layer INS6 may cover the second connection electrode CNE2 and may be disposed on the fifth insulating layer INS5.

Each of the first to sixth insulating layers INS1 to INS6 may include an inorganic layer or an organic layer. For example, the inorganic layer may include at least one of aluminum oxide, titanium oxide, silicon oxide, silicon oxynitride, zirconium oxide, or hafnium oxide. For example, the organic layer may include at least one of an acrylic resin, a methacrylic resin, a polyisoprene-based resin, a vinyl resin, an epoxy-based resin, a urethane-based resin, a cellulose-based resin, a siloxane-based resin, a polyamide-based resin, and/or a perylene-based resin.

The display element layer DP-EL may include a pixel defining layer PDL and a light emitting element ED. The light emitting element ED may include a first electrode AE, a hole control layer HCL, an emission layer EML, an electron control layer TCL, and a second electrode CE.

The light emitting element ED may emit light. For example, the light emitting element ED may include an organic light emitting material, an inorganic light emitting material, an organic-inorganic light emitting material, a quantum dot, or a quantum rod. For example, the light emitting element ED may include a micro LED or a nano LED.

The first electrode AE may be disposed on the sixth insulating layer INS6. The first electrode AE may be connected to the second connection electrode CNE2 through a third contact hole CH3 penetrating the sixth insulating layer INS6. The first electrode AE may be electrically connected to the drain D1 of the transistor TR through the first and second connection electrodes CNE1 and CNE2.

The first electrode AE may be formed using a metal material, a metal alloy, or a conductive compound. The first electrode AE may be an anode or a cathode. However, an embodiment of the present invention is not limited thereto. In addition, the first electrode AE may be a pixel electrode. For example, the first electrode AE may be a transmissive electrode, a semi-transmissive electrode, or a reflective electrode. For example, the first electrode AE may include at least one of Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

For example, if the first electrode AE is a transmissive electrode, the first electrode AE may include a transparent metal oxide, for example, indium tin oxide (ITO), indium zinc oxide (IZO), zinc oxide (ZnO), indium tin zinc oxide (ITZO), or the like. For example, if the first electrode AE is a semi-transmissive electrode or a reflective electrode, the first electrode AE may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (for example, a mixture of Ag and Mg). In addition, the first electrode AE may have a multilayer structure including a reflective film or a semi-transmissive film formed using the above materials and a transparent conductive film formed using indium tin oxide (ITO), indium zinc oxide (IZO), zinc oxide (ZnO), indium tin zinc oxide (ITZO), or the like. For example, the first electrode AE may have a three-layer structure of ITO/Ag/ITO, but an embodiment of the present invention is not limited thereto. In addition, the first electrode AE may include the above-described metal material, a combination of two or more metal materials selected from the above-described metal materials, or an oxide of the above-described metal materials, but an embodiment of the present invention is not limited thereto.

The pixel defining layer PDL may be disposed on the sixth insulating layer INS6. A light emitting opening PX_OP exposing a portion of the first electrode AE may be formed in the pixel defining layer PDL to provide a light emitting area LA. A portion of the first electrode AE exposed by the light emitting opening PX_OP may correspond to the light emitting area LA.

The display area DM-DA of the display module DM may include a light emitting area LA and a light shielding area NLA. The area where the pixel defining layer PDL is disposed may correspond to the light shielding area NLA. The light shielding area NLA may surround the light emitting area LA within the display area DM-DA.

A hole control layer HCL may be disposed on the first electrode AE and the pixel defining layer PDL. The hole control layer HCL may be provided as a common layer overlapping the light emitting area LA and the light shielding area NLA. The hole control layer HCL may include at least one of a hole transport layer, a hole injection layer, or an electron blocking layer. The hole control layer HCL may include a known hole injection material and/or a known hole transport material.

The emission layer EML may be disposed on the hole control layer HCL. The emission layer EML may be disposed in an area corresponding to the light emitting opening PX_OP. In addition, the emission layer EML may be provided as a common layer. The emission layer EML may include an organic light emitting material and/or an inorganic light emitting material. The emission layer EML may emit light of any one of red, green, or blue color. For example, the emission layer EML may emit blue light.

The electron control layer TCL may be disposed on the emission layer EML. The electron control layer TCL may be provided as a common layer overlapping the light emitting area LA and the light shielding area NLA. The electron control layer TCL may include at least one of an electron transport layer, an electron injection layer, and a hole blocking layer. The electron control layer TCL may include a known electron injection material and/or a known electron transport material.

The second electrode CE may be disposed on the electron control layer TCL. The second electrode CE may be provided as a common layer overlapping the light emitting area LA and the light shielding area NLA.

The second electrode CE may be a common electrode. The second electrode CE may be a cathode or an anode, but an embodiment of the present invention is not limited thereto. For example, if the first electrode AE is an anode, the second electrode CE may be a cathode, and if the first electrode AE is a cathode, the second electrode CE may be an anode.

The second electrode CE may be a transmissive electrode, a semi-transmissive electrode, or a reflective electrode. For example, if the second electrode CE is a transmissive electrode, the second electrode CE may be formed by using a transparent metal oxide such as indium tin oxide (ITO), indium zinc oxide (IZO), zinc oxide (ZnO), and indium tin zinc oxide (ITZO).

For example, if the second electrode CE is a semi-transmissive electrode or a reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, or a compound or mixture containing thereof (for example, AgMg, AgYb, or MgYb). In addition, the second electrode CE may have a multilayer structure including a reflective film or a semi-transmissive film formed using the above materials and a transparent conductive film formed using indium tin oxide (ITO), indium zinc oxide (IZO), zinc oxide (ZnO), or indium tin zinc oxide (ITZO). For example, the second electrode CE may include the above-described metal material, a combination of two or more metal materials selected from the above-described metal materials, or an oxide of the above-described metal materials.

The encapsulation layer TFE may be disposed on the display element layer DP-EL. The encapsulation layer TFE may be disposed on the second electrode CE to cover the light emitting element ED. The encapsulation layer TFE may protect the display element layer DP-EL from foreign substances such as moisture, oxygen, and/or dust particles. The encapsulation layer TFE may include a plurality of thin films.

The encapsulation layer TFE may include at least one inorganic film and an organic film. For example, the encapsulation layer TFE may include inorganic films, which are disposed on the second electrode CE, and an organic film disposed between the inorganic films. The inorganic film may protect the light emitting element ED from moisture/oxygen, and the organic film may protect the light emitting element ED from foreign substances such as dust particles.

The input sensing part TP may be disposed on the display panel DP. The input sensing part TP may be disposed on the encapsulation layer TFE. For example, the input sensing part TP may be directly disposed on the encapsulation layer TFE of the display panel DP. In addition, an adhesive layer may be disposed between the input sensing part TP and the display panel DP.

In the description, if one element is directly disposed/provided on another element, it means that no third element is disposed/provided between one element and the other element. In other words, if one element is “directly disposed/provided” on another element, it means that one element and the other element are “in contact” with each other.

The input sensing part TP may include a first sensing insulating layer IL1, a second sensing insulating layer IL2, and a third sensing insulating layer IL3. The input sensing part TP may include at least one conductive layer disposed on the sensing insulating layers. The input sensing part TP may include a first conductive layer CDL1 and a second conductive layer CDL2.

The first sensing insulating layer IL1 may be disposed on the encapsulation layer TFE. The first sensing insulating layer IL1 may include at least one inorganic insulating layer. For example, the first sensing insulating layer IL1 may be in contact with the encapsulation layer TFE. In addition, the first sensing insulating layer IL1 may be omitted, and in this case, the first conductive layer CDL1 may be in contact with the encapsulation layer TFE.

The first conductive layer CDL1 may be disposed on the first sensing insulating layer IL1. The first conductive layer CDL1 may include a plurality of first conductive patterns. The plurality of first conductive patterns may be disposed on the first sensing insulating layer IL1. The second sensing insulating layer IL2 may be disposed on the first sensing insulating layer IL1 so as to cover at least a portion of the first conductive layer CDL1.

The second conductive layer CDL2 may be disposed on the second sensing insulating layer IL2. The second conductive layer CDL2 may include a plurality of second conductive patterns. The plurality of second conductive patterns may be disposed on the second sensing insulating layer IL2. Each of the plurality of second conductive patterns may be connected to the plurality of first conductive patterns through a contact hole that is formed in the second sensing insulating layer IL2.

Each of the plurality of first conductive patterns of the first conductive layer CDL1 and the plurality of second conductive patterns of the second conductive layer CDL2 may be disposed corresponding to the light shielding area NLA. Each of the plurality of first conductive patterns of the first conductive layer CDL1 and the plurality of second conductive patterns of the second conductive layer CDL2 may have a mesh pattern.

The third sensing insulating layer IL3 may be disposed on the second sensing insulating layer IL2 and may cover the second conductive layer CDL2. Each of the second sensing insulating layer IL2 and the third sensing insulating layer IL3 may include an inorganic insulating layer or an organic insulating layer.

Each of the first conductive layer CDL1 and the second conductive layer CDL2 may have a single layer structure or a multilayer structure stacked along the third direction DR3. Each of the conductive layers CDL1 and CDL2 with a single layer structure may include a metal layer or a transparent conductive layer. The metal layer may include, for example, molybdenum, silver, titanium, copper, aluminum, or an alloy thereof. The transparent conductive layer may include, for example, a transparent conductive oxide such as indium tin oxide (ITO), indium zinc oxide (IZO), zinc oxide (ZnO), and indium tin zinc oxide (ITZO). In addition, the transparent conductive layer may include a conductive polymer such as PEDOT, a metal nanowire, graphene, or the like.

Each of conductive layers CDL1 and CDL2 with a multilayer structure may include metal layers. The metal layers may have a three layer structure of, for example, titanium (Ti)/aluminum (Al)/titanium (Ti). The conductive layers CDL1 and CDL2 with a multilayer structure may include at least one metal layer and at least one transparent conductive layer.

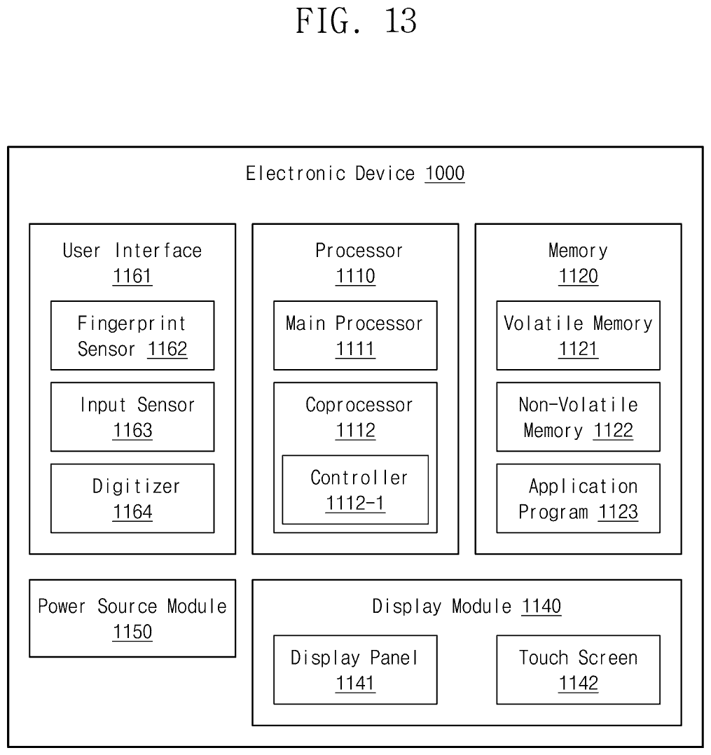

FIG. 13 is a diagram illustrating an electronic device (or, e.g., electronic apparatus) according to an embodiment of the present invention. Referring to FIG. 13, the electronic device 1000 according to an embodiment of the present invention may output various information (e.g., images, text, music, etc.) through a display module 1140, which, for example, may correspond to the display device DD shown in FIG. 8. When a processor 1110 executes an application stored in a memory 1120, the display module 1140 may provide application information to a user through a display panel 1141.

In some embodiments of the present invention, the electronic device 1000 may be configured as a smartphone, camera, smart TV, monitor, smartwatch, tablet, automotive display, or AR/VR headset. For example, the electronic device 1000 may be a smartphone including a touch-sensitive display area (e.g., first active area F-AA and/or second active area R-AA) for interaction and a non-display area (e.g., first peripheral area F-NAA and/or second peripheral area R-NAA) including sensors and circuits for enhanced functionality. For example, the electronic device 1000 may be a television or monitor including a large display area for high-resolution video playback and a non-display area incorporating driving circuits or connectivity modules for external inputs. For example, the electronic device 1000 may be a smartwatch including the display area optimized for compact and high-clarity visuals and the non-display area integrating biometric sensors for health monitoring. In some cases, the electronic device 1000 may be an AR/VR headset.

In some embodiments of the present invention, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device DD shown in FIG. 8.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display panel DP shown in FIG. 12.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

For example, the disclosure about the electronic device 1000 of FIG. 13 may be combinable with the disclosure about the electronic apparatus EA and EA-a.

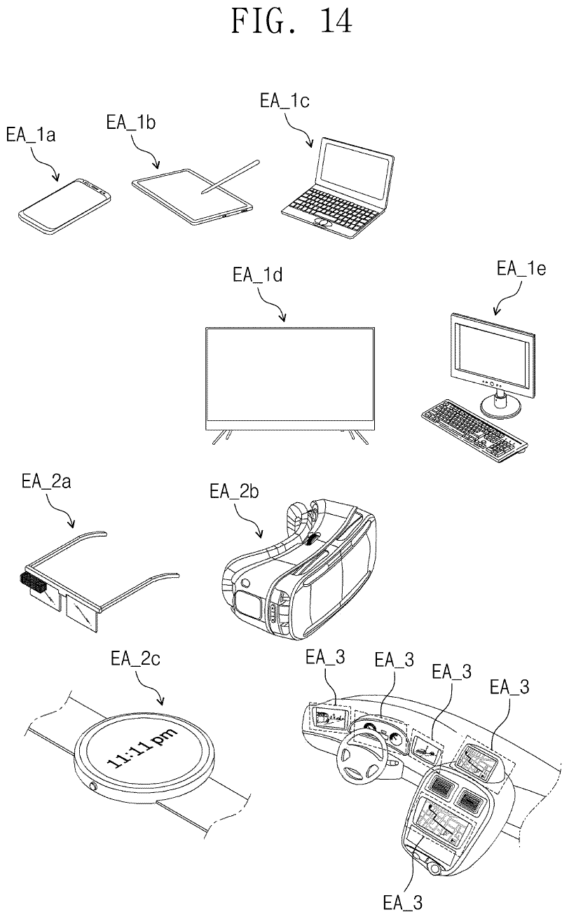

FIG. 14 is a schematic view illustrating electronic apparatuses according to various embodiments. Referring to FIG. 14, an electronic apparatus EA including the display device DD (see FIG. 8) according to an embodiment may include not only electronic apparatuses for displaying images, e.g., a smartphone EA_1a, a tablet computer (PC) EA_1b, a laptop computer EA_1c, TV EA_1d, and a monitor for a desk computer EA_1e, but also wearable electronic apparatuses including display devices, e.g., smart glasses EA_2a, a head mounted display EA_2b, and a smart watch EA_2c, and vehicle electronic apparatuses EA_3 including display devices, e.g., a vehicle instrument panel, a center fascia, a center information display (CID) disposed on a dashboard, and a room mirror display.

In an embodiment of the present invention, an electronic apparatus may include a display device. The display device may include a foldable display panel and a protective member disposed on the display panel. The protective member may include a protective base layer, a hard coating layer, and an antireflection layer, which are sequentially stacked. The hard coating layer includes a polymer derived from a coating composition, and the coating composition may include a silsesquioxane-based resin, an oxetane-based resin, a photopolymerization initiator, and silica nanoparticles. The weight of the silica nanoparticles may be about 3 wt % to about 5 wt % based on 100 wt % of the total weight of the coating composition. The hard coating layer is formed by curing the coating composition, and may exhibit low reflectivity, increased wear resistance, increased flexibility, and increased hardness. Accordingly, the hard coating layer may exhibit characteristics of low-curvature folding and easy repetition of folding and unfolding. A display device and an electronic apparatus including the hard coating layer may exhibit excellent reliability and excellent display quality.

A display device and an electronic apparatus including the same of an embodiment of the present invention include a hard coating layer formed from a coating composition including a certain material, and may have increased reliability.

Although the present invention has been described above with reference to embodiments thereof, it will be understood that those skilled in the art or having ordinary knowledge in the art can modify and change the present invention in various ways without departing from the spirit and technical scope of the present invention as described in the claims below.

While the present invention has been particularly shown and described with reference to embodiments thereof, it will be apparent to those of ordinary skill in the art that various changes in form and detail may be made thereto without departing from spirit and scope of the present invention.

What is claimed is:

1. A display device comprising:
a display panel configured to fold along a folding axis; and
a protective member disposed on the display panel,
wherein the protective member comprises:
a protective base layer;
a hard coating layer comprising a polymer derived from a coating composition, wherein the hard coating layer is disposed on the protective base layer; and
an antireflection layer comprising a high refractive index layer and a low refractive index layer disposed on the high refractive index layer, wherein the antireflection layer is disposed on the hard coating layer,
wherein the coating composition comprises a silsesquioxane-based resin, an oxetane-based resin, a photopolymerization initiator, and silica nanoparticles, and
wherein a first weight of the silica nanoparticles is about 3 wt % to about 5 wt % based on a total weight of the coating composition.

2. The display device of claim 1, wherein a sum of a second weight of the silsesquioxane-based resin and a third weight of the oxetane-based resin is about 93 wt % to about 95 wt % based on the total weight of the coating composition.

3. The display device of claim 1, wherein the silsesquioxane-based resin comprises at least one of a T-type silsesquioxane unit, a D-type silsesquioxane unit, or an M-type silsesquioxane unit.

4. The display device of claim 1, wherein the silsesquioxane-based resin comprises 7 or 8 siloxane units.

5. The display device of claim 1, wherein the oxetane-based resin comprises a moiety represented by a following Formula 1: 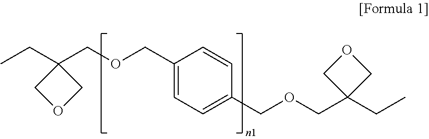
in Formula 1, n1 is an integer of 3 to 100.

6. The display device of claim 1, wherein the photopolymerization initiator comprises a triarylsulfonium hexafluoroantimonate salt.

7. The display device of claim 1, wherein a weight of the photopolymerization initiator is about 2 wt % or less based on the total weight of the coating composition.

8. The display device of claim 1, wherein a diameter of the silica nanoparticles is about 20 nm to about 60 nm.

9. The display device of claim 1, wherein the silica nanoparticle comprises a hydroxyl group on a surface thereof.

10. The display device of claim 1, wherein the coating composition further comprises a solvent, and the solvent comprises at least one of 1-methyoxy-2-methyl-2-propanol, 1-methoxy-2-propanol, or 2-butanone.

11. The display device of claim 1, wherein the high refractive index layer comprises niobium pentoxide (Nb₂O₅) and titanium dioxide (TiO₂), and
based on a sum of a fourth weight of the niobium pentoxide and a fifth weight of the titanium dioxide, a ratio of the fourth weight and the fifth weight is about 7:3 to about 9:1.

12. The display device of claim 1, wherein each of the high refractive index layer and the low refractive index layer is provided in multiples, and
the multiple high refractive index layers and the multiple low refractive index layers are alternately disposed on the hard coating layer.

13. The display device of claim 1, wherein a thickness of the hard coating layer is about 1 μm to about 8 μm.

14. The display device of claim 1, wherein the hard coating layer has a specular component included (SCI) reflectivity of about 0.5% to about 1.5%.

15. The display device of claim 1, wherein a hardness of the hard coating layer is about 0.22 GPa to about 0.32 GPa, and an elastic modulus of the hard coating layer is about 2.78 GPa to about 3.78 GPa.

16. The display device of claim 1, wherein the protective base layer comprises at least one among polyethylene terephthalate, polyimide, polyacrylate, polymethyl methacrylate, polycarbonate, polyethylene naphthalate, polyvinylidene chloride, polyvinylidene difluoride, polystyrene, or an ethylene vinyl alcohol copolymer.

17. An electronic apparatus comprising:
a display device including a module area; and
an electronic module disposed to correspond to the module area,
wherein the display device comprises:
a display panel configured to fold along a folding axis; and
a protective member disposed on the display panel,
wherein the protective member comprises:
a protective base layer;
a hard coating layer comprising a polymer derived from a coating composition, wherein the hard coating layer is disposed on the protective base layer; and
an antireflection layer comprising a high refractive index layer and a low refractive index layer disposed on the high refractive index layer, wherein the antireflection layer is disposed on the hard coating layer,
wherein the coating composition comprises a silsesquioxane-based resin, an oxetane-based resin, a photopolymerization initiator, and silica nanoparticles, and
wherein a first weight of the silica nanoparticles is about 3 wt % to about 5 wt % based on a total weight of the coating composition.

18. The electronic apparatus of claim 17, wherein a sum of a second weight of the silsesquioxane-based resin and a third weight of the oxetane-based resin is about 93 wt % to about 95 wt % based on the total weight of the coating composition.

19. The electronic apparatus of claim 17, wherein the photopolymerization initiator comprises a triarylsulfonium hexafluoroantimonate salt, and
the oxetane-based resin comprises a moiety represented by a following Formula 1: 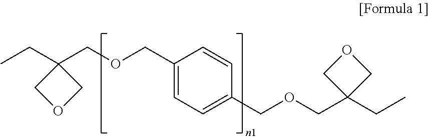
in Formula 1, n1 is an integer of 3 to 100.

20. An electronic apparatus, comprising:
a processor;
a memory having stored application programs for execution by the processor;
a display device, comprising:
a display panel configured to fold along a folding axis; and
a protective member disposed on the display panel,
wherein the protective member comprises:
a protective base layer;
a hard coating layer comprising a polymer derived from a coating composition, wherein the hard coating layer is disposed on the protective base layer; and
an antireflection layer comprising a high refractive index layer and a low refractive index layer disposed on the high refractive index layer, wherein the antireflection layer is disposed on the hard coating layer, wherein the high refractive index layer comprises niobium pentoxide and titanium dioxide,
wherein the coating composition comprises a silsesquioxane-based resin, an oxetane-based resin, a photopolymerization initiator, and silica nanoparticles, and
wherein a first weight of the silica nanoparticles is about 3 wt % to about 5 wt % based on a total weight of the coating composition; and
a user interface configured to sense user input via touch or cursor select of an icon presented on the display panel, wherein the processor is caused to execute one or more of the stored application programs upon receipt of the user input.
